(19) United States
(12) Patent Application Publication
(10) Pub. No.: US 2026/0271535 A1
(43) Pub. Date: Sep. 10, 2026

(54) DISPLAY PANEL AND ELECTRONIC DEVICE INCLUDING THE SAME

(71) Applicant: Samsung Display Co., Ltd., Yongin-si (KR)

(72) Inventors: Younjoo Ryu, Yongin-si (KR); Junho Sim, Yongin-si (KR); Sanghyun Yun, Yongin-si (KR); Jaehun Lee, Yongin-si (KR)

(21) Appl. No.: 19/397,258

(22) Filed: Nov. 21, 2025

(30) Foreign Application Priority Data
Mar. 6, 2025 (KR) 10-2025-0029204

(51) Int. Cl. H10K 59/122; H10K 59/80

(52) U.S. Cl. CPC H10K 59/122; H10K 59/873

(57) ABSTRACT

A display panel includes: a substrate comprising an opening; a plurality of light-emitting diodes in a display area surrounding the opening; a first partition wall in a non-display area between the opening and the display area, the first partition wall surrounding the opening; and a second partition wall in the non-display area, between the opening and the first partition wall, and surrounding the opening, wherein the first partition wall comprises a first surface toward the second partition wall and a second surface opposite to the first surface, wherein the first surface has a first concave portion open toward the second partition wall, and the second partition wall comprises a third surface toward the first partition wall and a fourth surface opposite to the third surface, wherein the third surface has a second concave portion open toward the first partition wall.

### CROSS-REFERENCE TO RELATED APPLICATION

The present application claims priority to and the benefit of Korean Patent Application No. 10-2025-0029204, filed on Mar. 6, 2025, in the Korean Intellectual Property Office, the entire disclosure of which is incorporated herein by reference.

### BACKGROUND

### Field

Aspects of one or more embodiments relate to a display panel and an electronic device including the same.

### Description of the Related Art

Recently, the use of display apparatuses has diversified. Moreover, display apparatuses have become relatively thinner and lighter over time, and thus, the range of uses thereof has expanded.

Various functions linked to or associated with display apparatuses may be added. In some display apparatuses various components may be arranged in display areas thereof as way of adding various functions while increasing the area.

The above information disclosed in this Background section is only for enhancement of understanding of the background and therefore the information discussed in this Background section does not necessarily constitute prior art.

### SUMMARY

A display apparatus may include an organic material with which a groove defined by organic layers is filled. Due to a step difference from a peripheral area, the groove may be non-uniformly filled with the organic material, and wrinkles, etc. of a display panel may be seen by users.

To solve various problems including the problems described above, a display panel having relatively improved reliability and display quality by uniformly filling an organic material between organic layers arranged adjacent to each other, and an electronic device including the display panel, are provided, according to some embodiments. However, these characteristics are merely examples and the scope of embodiments according to the present disclosure is not limited thereto.

Additional aspects will be set forth in part in the description which follows and, in part, will be apparent from the description, or may be learned by practice of the presented embodiments of the disclosure.

According to one or more embodiments, a display panel includes a substrate including an opening, a plurality of light-emitting diodes arranged in a display area surrounding the opening, a first partition wall arranged in a non-display area between the opening and the display area, the first partition wall surrounding the opening, and a second partition wall arranged in the non-display area, arranged between the opening and the first partition wall, and surrounding the opening, wherein the first partition wall includes a first surface toward the second partition wall and a second surface opposite to the first surface, wherein the first surface has a first concave portion open toward the second partition wall, and the second partition wall includes a third surface toward the first partition wall and a fourth surface opposite to the third surface, wherein the third surface has a second concave portion open toward the first partition wall.

According to some embodiments, the first concave portion and the second concave portion may be arranged to face each other.

According to some embodiments, the first concave portion and the second concave portion may each be provided as a plurality, the plurality of first concave portions may be arranged to be apart from each other along the first surface, and the plurality of second concave portions may be arranged to be apart from each other along the third surface.

According to some embodiments, each of the first concave portion and the second concave portion may have at least one vertex at which two edges extending in different directions intersect in a plan view.

According to some embodiments, the two edges meeting each other at the at least one vertex may form an acute angle in the plan view.

According to some embodiments, the acute angle formed by the two edges meeting each other at the at least one vertex may be greater than 40°.

According to some embodiments, the first concave portion and the second concave portion may have an axially symmetrical shape in a plan view.

According to some embodiments, the number of vertices of the first concave portion may be different from the number of vertices of the second concave portion.

According to some embodiments, the display panel may further include an overhang structure arranged in the non-display area and surrounding the opening, wherein the overhang structure may include a first layer in which a groove is defined and second layers arranged at both sides of the groove, wherein each of the second layers may include an overhang portion hanging over the groove and extending toward each other.

According to some embodiments, the overhang portion may be tilted toward the groove and forms an angle of 0° to 40° with a virtual plane parallel to an upper surface of the substrate.

According to some embodiments, the first layer may include an organic insulating material, and the second layers may include a metal material.

According to one or more embodiments, a display panel includes a substrate including a display area and a peripheral area outside the display area, a plurality of light-emitting diodes arranged in the display area, an encapsulation layer arranged on the plurality of light-emitting diodes, and an optical functional layer arranged on the encapsulation layer and including an organic layer and a plurality of light-shielding lines, wherein the organic layer defines a plurality of grooves and the plurality of light-shielding lines are arranged in the plurality of grooves, wherein each of the plurality of light-shielding lines includes a first protrusion portion extending in a first direction and protruding in a second direction crossing the first direction and a second protrusion portion protruding in a third direction which is opposite to the second direction.

According to some embodiments, the first protrusion portion and the second protrusion portion may be arranged in alignment with each other.

According to some embodiments, the first protrusion portion and the second protrusion portion may each be provided as a plurality, the plurality of first protrusion portions may be arranged to be apart from each other along the plurality of light-shielding lines, and the plurality of second protrusion portions may be arranged in alignment with the plurality of first protrusion portions.

According to some embodiments, each of the first protrusion portion and the second protrusion portion may have at least one vertex at which two edges extending in different directions intersect in a plan view.

According to some embodiments, the two edges intersecting each other at the at least one vertex may form an acute angle in the plan view.

According to some embodiments, the acute angle formed by the two edges meeting each other at the at least one vertex may be greater than 40°.

According to one or more embodiments, an electronic device includes a display apparatus including a display panel, a memory storing an application, and a processor configured to execute the application and transmit an image data signal and a control signal to the display apparatus, wherein the display panel includes a first organic layer and a second organic layer arranged on a substrate and arranged to be apart from each other by a certain distance to define a valley area or a groove, and a third organic layer filling the valley area or the groove, wherein the first organic layer includes a first surface toward the second organic layer, and the second organic layer includes a third surface toward the first organic layer, wherein the first surface has a first concave portion open toward the second organic layer, and the third surface has a second concave portion open toward the first organic layer.

According to some embodiments, the substrate may include an opening, the electronic device may include a plurality of light-emitting diodes arranged in a display area surrounding the opening, and the first organic layer and the second organic layer may be arranged in a non-display area between the opening and the display area and surround the opening.

According to some embodiments, the electronic device may further include a plurality of light-emitting diodes arranged on the substrate and an encapsulation layer arranged on the plurality of light-emitting diodes, wherein the first organic layer and the second organic layer may be arranged on the encapsulation layer, and the third organic layer may include a light-shielding material.

These general and specific embodiments may be implemented by using a system, a method, a computer program, or a combination of the system, the method, and the computer program.

### BRIEF DESCRIPTION OF THE DRAWINGS

The above and other aspects, features, and characteristics of certain embodiments of the disclosure will be more apparent from the following description taken in conjunction with the accompanying drawings, in which:

FIG. 1 is a schematic perspective view of a display apparatus according to some embodiments;

FIG. 2 is a schematic cross-sectional view of a display apparatus taken along the line I-I' of FIG. 1, according to some embodiments;

FIG. 3 is a schematic plan view of a display panel according to some embodiments;

FIGS. 4A and 4B are each a schematic equivalent circuit diagram of a light-emitting diode and a circuit connected to the light-emitting diode, according to some embodiments;

FIG. 5 is a schematic plan view of a portion of a display panel according to some embodiments;

FIG. 6 is a schematic cross-sectional view of a display panel taken along the line IV-IV' of FIG. 5, according to some embodiments;

FIG. 7 is a schematic cross-sectional view of a display panel taken along the line V-V' of FIG. 5, according to some embodiments;

FIG. 8 is an enlarged schematic cross-sectional view of a portion of a display panel, the portion corresponding to region VI of FIG. 7, according to some embodiments;

FIG. 9A is an enlarged schematic plan view of a portion of a display panel, the portion corresponding to region III of FIG. 5, according to some embodiments;

FIGS. 9B to 9D are each a plan view of a portion of a display panel according to some embodiments;

FIG. 10 is a schematic perspective view of a display apparatus according to some embodiments;

FIG. 11 is a schematic cross-sectional view of a display apparatus taken along the line VII-VII' of FIG. 10, according to some embodiments;

FIG. 12 is a schematic equivalent circuit diagram of a light-emitting diode and a circuit connected to the light-emitting diode, according to some embodiments;

FIG. 13 is a schematic plan view of a portion of a display panel according to some embodiments;

FIG. 14 is a schematic cross-sectional view of a portion of a display panel according to some embodiments;

FIG. 15A is an enlarged schematic plan view of a portion of a display panel, the portion corresponding to region VIII of FIG. 13, according to some embodiments;

FIGS. 15B and 15C are each a plan view of a portion of a display panel according to some embodiments;

FIG. 16 is a schematic block diagram of an electronic device according to some embodiments; and

FIGS. 17 to 19 are schematic views of electronic devices according to some embodiments.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term "and/or" includes any and all combinations of one or more of the associated listed items. Throughout the disclosure, the expression "at least one of a, b or c" indicates only a, only b, only c, both a and b, both a and c, both b and c, all of a, b, and c, or variations thereof.

While the disclosure is capable of having various modifications and alternative forms, embodiments thereof are shown by way of example in the drawings and will herein be described in detail. The effects and characteristics of the disclosure and methods of achieving the same will become apparent by referring to the embodiments described below in detail with reference to the drawings. However, the disclosure is not limited to the embodiments disclosed hereinafter and may be realized in various forms.

Hereinafter, embodiments will be described in detail by referring to the accompanying drawings, wherein, when describing the accompanying drawings, elements that are the same as or corresponding to each other will be assigned the same reference numerals, repeated descriptions thereof will not be given.

It will be understood that although the terms "first," "second," etc. may be used herein to describe various components, these components should not be limited by these terms. These components are only used to distinguish one component from another.

As used herein, the singular expressions "a," "an," and "the" are intended to include the plural forms as well, unless the context clearly indicates otherwise.

It will be further understood that the terms "comprises" and/or "comprising" used herein specify the presence of stated features or components, but do not preclude the presence or addition of one or more other features or components.

It will be understood that when a layer, region, or element is referred to as being formed "on" another layer, area, or element, it can be directly or indirectly formed on the other layer, region, or element. That is, for example, intervening layers, regions, or elements may be present.

In this specification, it will be understood that when an element, an area, or a layer is referred to as being connected to another element, area, or layer, it can be directly and/or indirectly connected to the other element, area, or layer. For example, it will be understood in this specification that when an element, an area, or a layer is referred to as being in contact with or being electrically connected to another element, area, or layer, it can be directly and/or indirectly in contact with or electrically connected to the other element, area, or layer.

In this specification, the expression "A and/or B" may indicate A, B, or A and B. Also, the expression "at least one of A and B" may indicate A, B, or A and B.

In this specification, an x direction, a y direction, and a z direction are not limited to directions in three axes on a rectangular coordinate system and may be interpreted in a broader sense. For example, the x direction, the y direction, and the z direction may be orthogonal to one another or may refer to different directions that are not orthogonal to one another.

In this specification, the expression "in a plan view" denotes that an object part is downwardly viewed (for example, in a direction perpendicular to an upper surface of a substrate), and the expression "in a cross-sectional view" denotes that a vertical cross-section of an object part is laterally viewed.

In this specification, that a first element "overlaps" a second element denotes that the first element is located above or below the second element so that at least portions of the first element and the second element overlap each other in a plan view.

In this specification, when a certain embodiment may be implemented differently, a specific process order may be performed differently from the described order. For example, two consecutively described processes may be performed at the same time (or substantially at the same time) or performed in an order opposite to the described order.

Also, for convenience of explanation, elements in the drawings may have exaggerated or reduced sizes. For example, sizes and thicknesses of the elements in the drawings are randomly indicated for convenience of explanation, and thus, the disclosure is not necessarily limited to the illustrations of the drawings.

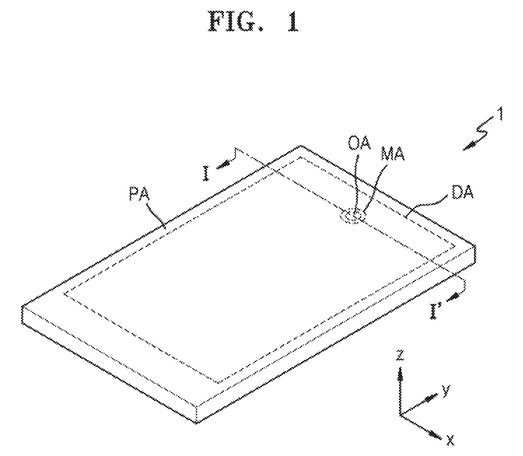

FIG. 1 is a schematic perspective view of a display apparatus 1 according to some embodiments.

Referring to FIG. 1, the display apparatus 1 may include an apparatus for displaying video images (e.g., moving or dynamic images) or static images (e.g., still images) and may be used as a display screen not only of a portable electronic device, such as a mobile phone, a smartphone, a tablet personal computer (PC), a mobile communication terminal, an electronic notebook, an electronic book, a portable multimedia player (PMP), a navigation device, or a ultra-mobile PC (UMPC), but also of various electronic devices, such as a television, a notebook computer, a monitor, an advertising board, and an Internet of things (IOT) device. FIG. 1 illustrates that the display apparatus 1 according to some embodiments is used as a smartphone, for convenience of explanation, but embodiments according to the present disclosure are not limited thereto.

According to some embodiments, the display apparatus 1 may have a rectangular shape in a plan view. For example, the display apparatus 1 may have a rectangular planar shape having a short side in an x direction and a long side in a y direction as illustrated in FIG. 1. A corner at which the short side in the x direction and the long side in the y direction meet each other may be curved to have a curvature (e.g., a set or predetermined curvature) or may be right-angled. A planar shape of the display apparatus 1 is not limited to the rectangular planar shape and may include other shapes, such as a polygonal shape, an oval shape, or an amorphous shape.

The display apparatus 1 may include an opening area OA (or a first area) and a display area DA (or a second area) surrounding at least a portion of the opening area OA. The display apparatus 1 may include a non-display area MA (or a third area) adjacent to the opening area OA and arranged at an inner side of the display area DA and a peripheral area PA (or a fourth area) arranged at an outer side of the display area DA. The non-display area MA may have a closed-loop shape entirely surrounding (e.g., in a periphery or outside a footprint of) the opening area OA in a plan view, and may be entirely surrounded by the display area DA. The peripheral area PA may entirely surround (e.g., in a periphery or outside a footprint of) the display area DA in a plan view.

The opening area OA may be arranged at an inner side of the display area DA. According to some embodiments, the opening area OA may be arranged at an upper middle side of the display area DA as illustrated in FIG. 1. Alternatively, the opening area OA may be arranged at an upper left side or an upper right side of the display area DA. Like this, the opening area OA may be arranged in various fashions. FIG. 1 illustrates that one opening area OA is arranged. However, according to some embodiments, a plurality of opening areas OA may be arranged.

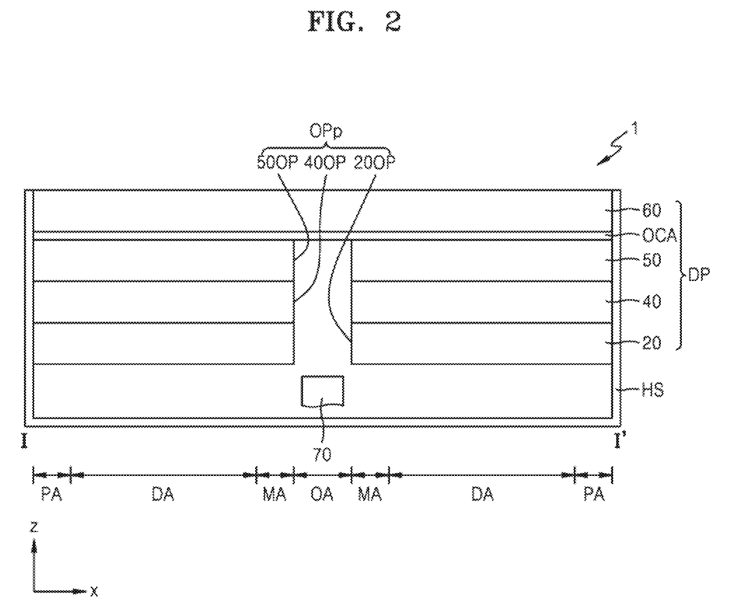

FIG. 2 is a schematic cross-sectional view of the display apparatus 1 taken along the line I-I' of FIG. 1, according to some embodiments.

Referring to FIG. 2, the display apparatus 1 may include a display panel DP and a component 70 arranged in the opening area OA of the display panel DP. The display panel DP and the component 70 may be accommodated in a housing HS.

The display panel DP may include an image generation layer 20, an input sensing layer 40, an optical functional layer 50, and a cover window 60.

The image generation layer 20 may include display elements (or light-emitting elements) emitting light to display images. The display element may include a light-emitting diode, for example, an organic light-emitting diode including an organic emission layer. According to some embodiments, the light-emitting diode may include an inorganic light-emitting diode including an inorganic material. The inorganic light-emitting diode may include a PN junction diode including inorganic semiconductor-based materials. When a voltage is applied to the PN junction diode in a normal direction, holes and electrons may be injected into the PN junction diode and energy generated by recombination of the holes and the electrons may be converted into light energy, and thus, light of a certain color may be emitted. The inorganic light-emitting diode described above may have a width that is several to hundreds of micrometers or several to hundreds of nanometers.

According to some embodiments, the image generation layer 20 may include a quantum dot light-emitting diode. For example, an emission layer of the image generation layer 20 may include an organic material, an inorganic material, quantum dots, an organic material and quantum dots, or an inorganic material and quantum dots.

The input sensing layer 40 may obtain coordinate information based on an external input, for example, a touch event. The input sensing layer 40 may include a sensing electrode (or a touch electrode) and trace lines connected to the sensing electrode (or the touch electrode). The input sensing layer 40 may be arranged above the image generation layer 20. The input sensing layer 40 may sense an external input by using a mutual cap method and/or a self-cap method.

The input sensing layer 40 may be directly formed on the image generation layer 20 or may be coupled to the image generation layer 20 through an adhesive layer, such as an optical clear adhesive (OCA), after being separately formed. For example, a process of forming the input sensing layer 40 may be sequentially performed after a process of forming the image generation layer 20, and in this case, the adhesive layer may not be arranged between the input sensing layer 40 and the image generation layer 20. FIG. 2 illustrates that the input sensing layer 40 is arranged between the image generation layer 20 and the optical functional layer 50. However, according to some embodiments, the input sensing layer 40 may be arranged above the optical functional layer 50.

The optical functional layer 50 may include a reflection prevention layer. The reflection prevention layer may reduce the reflectivity of light (external light) incident toward the display panel DP from the outside through the cover window 60. The reflection prevention layer may include a phase retarder and a polarizer. According to some embodiments, the reflection prevention layer may include a black matrix and color filters. The color filters may be arranged by taking into account a color of light emitted from each of the light-emitting diodes of the image generation layer 20.

In order to relatively improve the transmittance of the opening area OA, the display panel DP may include a panel opening OPp passing through some of layers included in the display panel DP. The panel opening OPp may include first to third openings 20OP, 40OP, and 50OP respectively passing through the image generation layer 20, the input sensing layer 40, and the optical functional layer 50. The first opening 20OP of the image generation layer 20, the second opening 40OP of the input sensing layer 40, and the third opening 50OP of the optical functional layer 50 may overlap each other to form the panel opening OPp passing through the image generation layer 20, the input sensing layer 40, and the optical functional layer 50.

The cover window 60 may be arranged on the optical functional layer 50. The cover window 60 may be coupled to the optical function layer 50 through an adhesive layer, such as an OCA, arranged therebetween. The cover window 60 may cover the first opening 20OP of the image generation layer 20, the second opening 40OP of the input sensing layer 40, and the third opening 50OP of the optical functional layer 50.

The cover window 60 may include a glass material or a plastic material. The glass material may include ultra-thin glass. The plastic material may include polyether sulfone, polyacrylate, polyether imide, polyethylene naphthalate, polyethylene terephthalate, polyphenylene sulfide, polyarylate, polyimide, polycarbonate, cellulose acetate propionate, or the like.

The opening area OA may be a type of component area (for example, a sensor area, a camera area, a speaker area, etc.), in which the component 70 for adding various functions to the display apparatus 1 is arranged.

The component 70 may include an electronic element. For example, the component 70 may include the electronic element using light or sound. For example, the electronic element may include a sensor configured to use light, such as an infrared sensor, a camera configured to receive light and capture an image, a sensor configured to measure a distance or recognize a fingerprint, etc. by outputting and sensing light or sound, a small lamp configured to output light, a speaker configured to output sound, etc. The electronic element using light may use pieces of light of various wavelength ranges, such as visible rays, infrared rays, ultraviolet rays, etc. The opening area OA may correspond to an area through which light and/or sound output from the component 70 to the outside or proceeding from the outside toward the electronic element are/is transmitted.

The opening area OA may be arranged at an inner side of the display area DA. The non-display area MA may be arranged between the opening area OA and the display area DA. The non-display area MA may have a closed-loop shape entirely surrounding the opening area OA. The peripheral area PA may be arranged at an outer side of the display area DA and may entirely surround the display area DA.

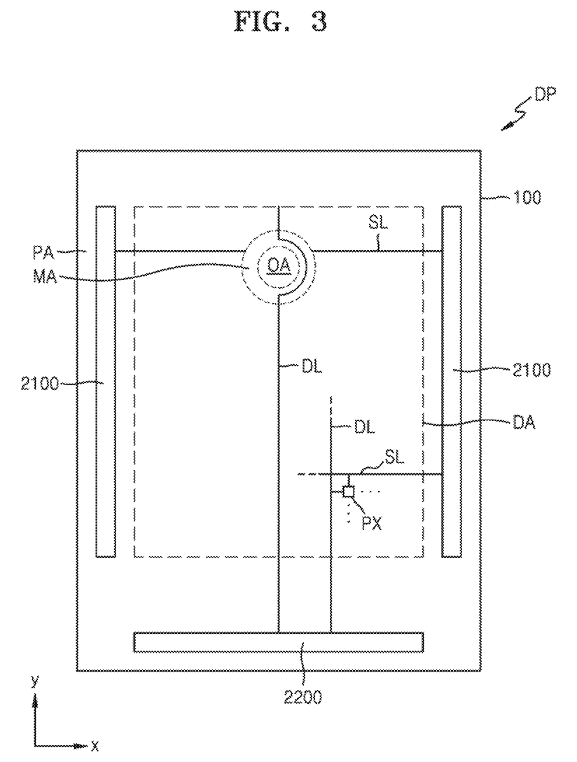

FIG. 3 is a schematic plan view of the display panel DP according to some embodiments.

Referring to FIG. 3, the display panel DP may include the opening area OA, the display area DA, the non-display area MA, and the peripheral area PA.

The display panel DP may include a plurality of pixels PX arranged in the display area DA and may display an image by using light emitted from each of the plurality of pixels PX. Each pixel PX may emit red, green, or blue light by using a light-emitting diode. The light-emitting diode of each pixel may be electrically connected to a scan line SL and a data line DL.

A scan driver 2100 configured to provide a scan signal to each pixel PX, a data driver 2200 configured to provide a data signal to each pixel PX, and a first power voltage supply line and a second power voltage supply line configured to provide a first power voltage and a second power voltage may be arranged in the peripheral area PA. The scan driver 2100 may be arranged at both sides of the display area DA. In this case, a pixel PX arranged at a left side with respect to the opening OA may be connected to the scan driver 2100 arranged at the left side, and a pixel PX arranged at a right side with respect to the opening OA may be connected to the scan driver 2100 arranged at the right side.

The non-display area MA may be arranged between the display area DA and the opening area OA and may surround the opening OA in a plan view. The non-display area MA may be an area in which a display element, such as a light-emitting diode, that emits light is not arranged, and signal lines configured to provide signals to the pixels PX arranged around the opening area OA may cross the non-display area MA. For example, while the data lines DL and/or the scan lines SL may cross the display area DA, some of the data lines DL and/or the scan lines SL may bypass the non-display area MA along an edge of the panel opening OPp (see FIG. 2) formed in the opening area OA. According to some embodiments, FIG. 3 illustrates that while the data lines DL may cross the display area DA in a y direction, some of the data lines DL may bypass the non-display area MA to partially surround the opening area OA. While the scan lines SL may cross the display area DA in an x direction, the scan lines SL may be apart from each other with the opening OA therebetween.

FIG. 3 illustrates that the data driver 2200 may be arranged to be adjacent to one side of a substrate 100. However, according to some embodiments, the data driver 2200 may be arranged on a printed circuit board (PCB) electrically connected to a pad arranged on a side of the display panel DP. The PCB may be flexible, and a portion of the PCB may be bent to be located below a rear surface of the substrate 100.

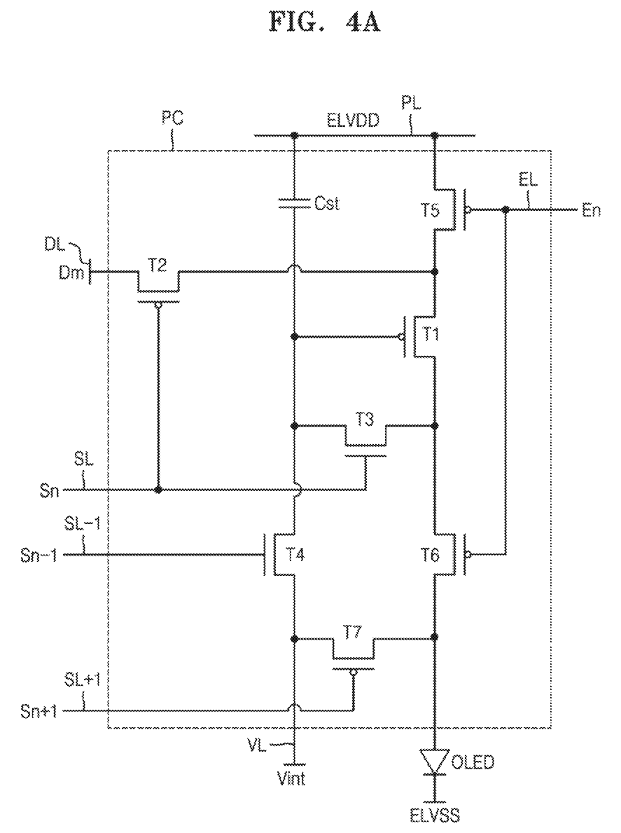

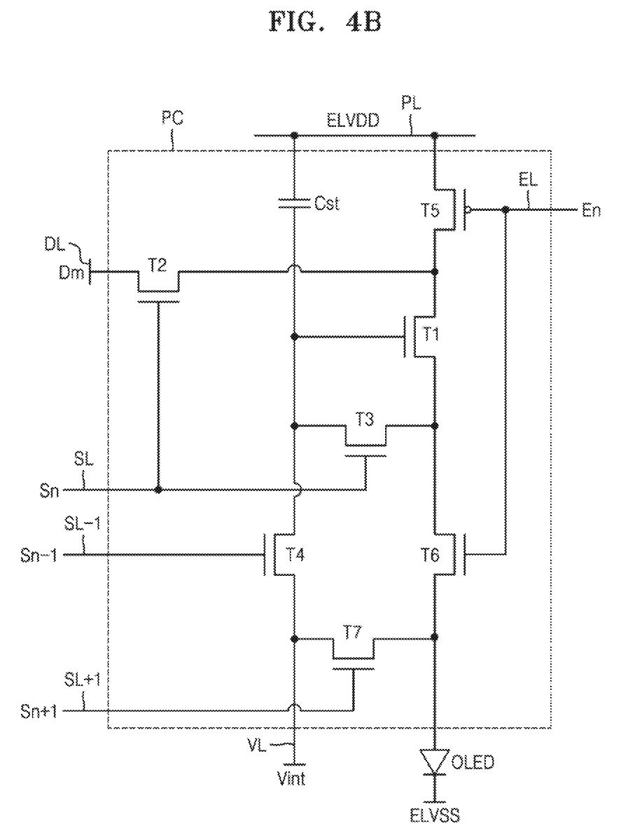

FIGS. 4A and 4B are each a schematic equivalent circuit diagram of a light-emitting diode and a circuit connected to the light-emitting diode, according to some embodiments. Although FIGS. 4A and 4B illustrate various components thereof according to some embodiments, embodiments according to the present disclosure are not limited thereto, and according to some embodiments, the circuits may include additional components or fewer components without departing from the spirit and scope of embodiments according to the present disclosure.

Referring to FIGS. 4A and 4B, the pixel PX (see FIG. 3) may emit light through a display element, for example, an organic light-emitting diode OLED, and the organic light-emitting diode OLED may be electrically connected to a pixel circuit PC.

The pixel circuit PC may include a first transistor T1, a second transistor T2, a third transistor T3, a fourth transistor T4, a fifth transistor T5, a sixth transistor T6, a seventh transistor T7, and a storage capacitor Cst.

Some of the first to seventh transistors T1 to T7 may include n-channel metal-oxide semiconductor field effect transistors (n-channel MOSFET) (NMOS transistors), and the others may include p-channel metal-oxide semiconductor field-effect transistors (p-channel MOSFET) (PMOS transistors). According to some embodiments, as illustrated in FIG. 4A, the third transistor T3 and the fourth transistor T4 from among the first to seventh transistors T1 to T7 may correspond to NMOS transistors, and the remaining transistors may correspond to PMOS transistors. According to some embodiments, as illustrated in FIG. 4B, the fifth transistor T5 from among the first to seventh transistors T1 to T7 may correspond to a PMOS transistor, and the remaining transistors may correspond to NMOS transistors.

At least one of the first to seventh transistors T1 to T7 may include a transistor having a low-temperature polycrystalline silicon (LTPS) semiconductor layer, and at least one of the first to seventh transistors T1 to T7 may include a transistor having an oxide semiconductor layer. According to some embodiments, the third transistor T3 and the fourth transistor T4 illustrated in FIG. 4A may include an oxide semiconductor layer having a low leakage current, and the first, second, fifth, sixth, and seventh transistors T1, T2, T5, T6, and T7 may include a semiconductor layer including polycrystalline silicon. According to some embodiments, the fifth transistor T5 illustrated in FIG. 4B may include a semiconductor layer including polycrystalline silicon, and the first, second, third, fourth, sixth, and seventh transistors T1, T2, T3, T4, T6, and T7 may include an oxide semiconductor layer.

Each of the first to seventh transistors T1 to T7 may include a gate (or a gate electrode), a first terminal (or a first electrode), and a second terminal (or a second electrode). Each first terminal may correspond to a source or a drain, and each second terminal may be a different terminal from the first terminal. For example, when the first terminal corresponds to the source (a source electrode), the second terminal may correspond to the drain (a drain electrode).

The second transistor T2 may include a switching transistor, may be connected to a scan line SL and a data line DL, and may be configured to transmit, to the first transistor T1, a data voltage (or a data signal Dm) input from the data line DL, based on a switching voltage (or a switching signal Sn) input from the scan line SL. The storage capacitor Cst may be connected to the second transistor T2 and a driving voltage line PL and may be configured to store a voltage corresponding to the difference between a voltage received from the second transistor T2 and a driving voltage (or a first power voltage ELVDD) supplied to the driving voltage line PL.

The first transistor T1 may include a driving transistor, may be connected to the driving voltage line PL and the storage capacitor Cst, and may be configured to control a driving current flowing from the driving voltage line PL through the organic light-emitting diode OLED according to a value of the voltage stored in the storage capacitor Cst. The organic light-emitting diode OLED may emit light having a certain brightness according to the driving current. A second electrode (for example, a cathode) of the organic light-emitting diode OLED may receive a common voltage ELVSS.

The third transistor T3 may include a compensation transistor and the gate of the third transistor T3 may be connected to the scan line SL. The first terminal of the third transistor T3 may be connected to any one electrode of the storage capacitor Cst, the first electrode of the fourth transistor T4, and the gate of the first transistor T1. The second terminal of the third transistor T3 may be connected to the second terminal of the first transistor T1 and may be electrically connected to a first electrode of the organic light-emitting diode OLED through the sixth transistor T6. The third transistor T3 may be turned on in response to a scan signal Sn received through the scan line SL and may diode-connect the first transistor T1.

The fourth transistor T4 may include an initialization transistor and the gate of the fourth transistor T4 may be connected to a previous scan line SL-1. The first terminal of the fourth transistor T4 may be connected to any one electrode of the storage capacitor Cst, the first terminal of the third transistor T3, and the gate of the first transistor T1. The second terminal of the fourth transistor T4 may be connected to an initialization voltage line VL. The fourth transistor T4 may be turned on in response to a previous scan signal Sn-1 received through the previous scan line SL-1 and may perform an initialization operation of initializing the gate of the first transistor T1 by transmitting an initialization voltage Vint to the gate of the first transistor T1.

The fifth transistor T5 may include an operation control transistor and the gate of the fifth transistor T5 may be connected to an emission control line EL. The first terminal of the fifth transistor T5 may be connected to the driving voltage line PL. The second terminal of the fifth transistor T5 may be connected to the first terminal of the first transistor T1 and the second terminal of the second transistor T2.

The sixth transistor T6 may include an emission control transistor and the gate of the sixth transistor T6 may be connected to the emission control line EL. The first terminal of the sixth transistor T6 may be connected to the second terminal of the first transistor T1 and the second terminal of the third transistor T3. The second terminal of the sixth transistor T6 may be electrically connected to a pixel electrode (for example, an anode) of the organic light-emitting diode OLED. The fifth transistor T5 and the sixth transistor T6 may be configured to be simultaneously (or concurrently) turned on according to an emission control signal En received through the emission control line EL so that driving currents may flow through the organic light-emitting diode OLED.

The seventh transistor T7 may include an initialization transistor configured to initialize the pixel electrode of the organic light-emitting diode OLED. The gate of the seventh transistor T7 may be connected to a next scan line SL+1. The first terminal of the seventh transistor T7 may be connected to the initialization voltage line VL. The second terminal of the seventh transistor T7 may be connected to the first electrode of the organic light-emitting diode OLED. The seventh transistor T7 may be turned on in response to a next scan signal Sn+1 received through the next scan line SL+1 and may be configured to initialize the pixel electrode of the organic light-emitting diode OLED.

FIGS. 4A and 4B illustrate the case where the fourth transistor T4 and the seventh transistor T7 are respectively connected to the previous scan line SL-1 and the next scan line SL+1. However, embodiments according to the present disclosure are not limited thereto. According to some embodiments, both of the fourth transistor T4 and the seventh transistor T7 may be connected to the previous scan line SL-1 and driven according to the previous scan signal Sn-1.

Any one electrode of the storage capacitor Cst may be connected to the driving voltage line PL. The other electrode of the storage capacitor Cst may be connected to the gate of the first transistor T1, the first terminal of the third transistor T3, and the first terminal of the fourth transistor T4.

An opposite electrode (for example, a cathode) of the organic light-emitting diode OLED may receive a common voltage (for example, a second power voltage ELVSS). The organic light-emitting diode OLED may emit light by a brightness corresponding to the driving current supplied from the first transistor T1.

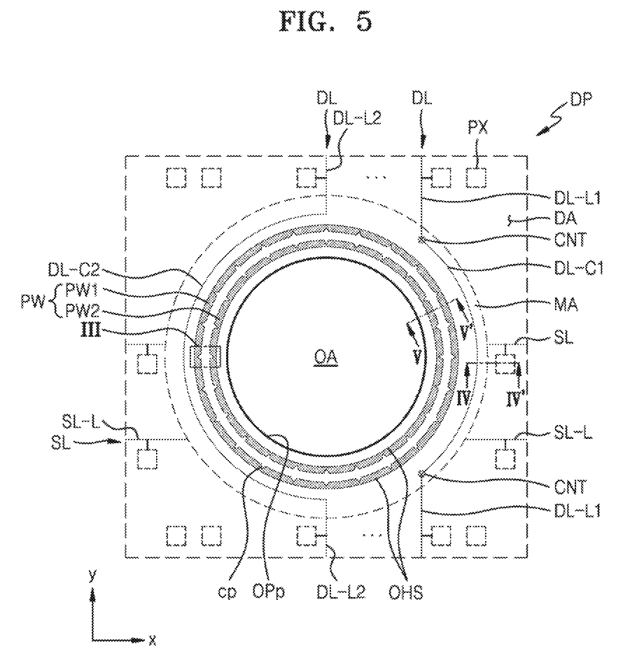

FIG. 5 is a schematic plan view of a portion of the display panel DP according to some embodiments.

Referring to FIG. 5, the display panel DP may include the panel opening OPp. The panel opening OPp may be arranged in the opening area OA, and the pixels PX may be arranged in the display area DA. The non-display area MA may be arranged between the opening area OA and the display area DA. The pixels PX adjacent to the opening area OA may be arranged to be apart from each other with respect to the opening area OA in a plan view. In a plan view of FIG. 5, the pixels PX may be arranged to be apart from each other in an upper or lower direction with respect to the opening area OA or in a right or left direction with respect to the opening area OA. Each pixel PX may use red, green, or blue light emitted from a light-emitting diode, and thus, the position of each pixel PX illustrated in FIG. 5 may correspond to the position of each light-emitting diode. Thus, that the pixels PX are arranged to be apart from each other with respect to the opening area OA in a plan view may indicate that the light-emitting diodes are arranged to be apart from each other with respect to the opening area OA in a plan view. For example, in a plan view, the light-emitting diodes may be arranged to be apart from each other in an upper or lower direction with respect to the opening area OA or in a right or left direction with respect to the opening area OA.

Signal lines adjacent to the opening area OA from among signal lines configured to supply signals to a pixel circuit connected to the light-emitting diode of each pixel PX may bypass the opening area OA and/or the panel opening OPp. While some of data lines DL crossing the display area DA may extend in ±y directions to provide a data signal to the pixels PX respectively arranged above and below the opening area OA, the data lines DL may bypass the non-display area MA along an edge of the opening area OA and/or the panel opening OPp.

A bypass portion DL-D1 of at least one data line DL from among the data lines DL may be formed on a different layer from an extension portion DL-L1 of the data line DL crossing the display area DA. Also, the bypass portion DL-D1 and the extension portion DL-L1 of the data line DL may be in contact with each other through a contact hole CNT. A bypass portion DL-D2 of at least one data line DL from among the data lines DL may be arranged on the same layer as and integrally formed with an extension portion DL-L2 of the at least one data line DL.

Scan lines SL may be separated or disconnected with respect to the opening area OA. Also, the scan line SL arranged at the left side with respect to the opening OA may be configured to receive a signal from the scan driver 2100 arranged at the left side with respect to the display area DA, and the scan line SL arranged at the right side with respect to the opening area OA may be configured to receive a signal from the scan driver 2100 arranged at the right side with respect to the display area DA illustrated in FIG. 3, as described above with reference to FIG. 3.

At least two organic layers having a step difference from a peripheral area may be arranged between a region of the non-display area MA, which is bypassed by the data lines DL, and the opening area OA. For example, at least two partition walls PW may be arranged in the non-display area MA. The partition walls PW may include a first partition wall PW1 surrounding the opening area OA and/or the panel opening OPp and a second partition wall PW2 arranged between the opening area OA and/or the panel opening OPp and the first partition wall PW1. In a plan view, each of the partition walls PW may have a closed-loop shape surrounding the opening area OA. The first partition wall PW1 and the second partition wall PW2 may be apart from each other by a certain distance. For example, the first partition wall PW1 and the second partition wall PW2 may include concentric circles surrounding the opening area OA.

A valley area having a bottom surface lower than an upper surface of the first partition wall PW1 and an upper surface of the second partition wall PW2 may be defined between the first partition wall PW1 and the second partition wall PW2. Each of the first partition wall PW1 and the second partition wall PW2 may have, on a surface thereof facing the valley area, concave portions cp apart from each other. The concave portions cp may help smooth distribution of an organic material, so that the organic material may relatively uniformly fill the valley area, when the organic material is applied between the first partition wall PW1 and the second partition wall PW2 which are arranged to be adjacent to each other.

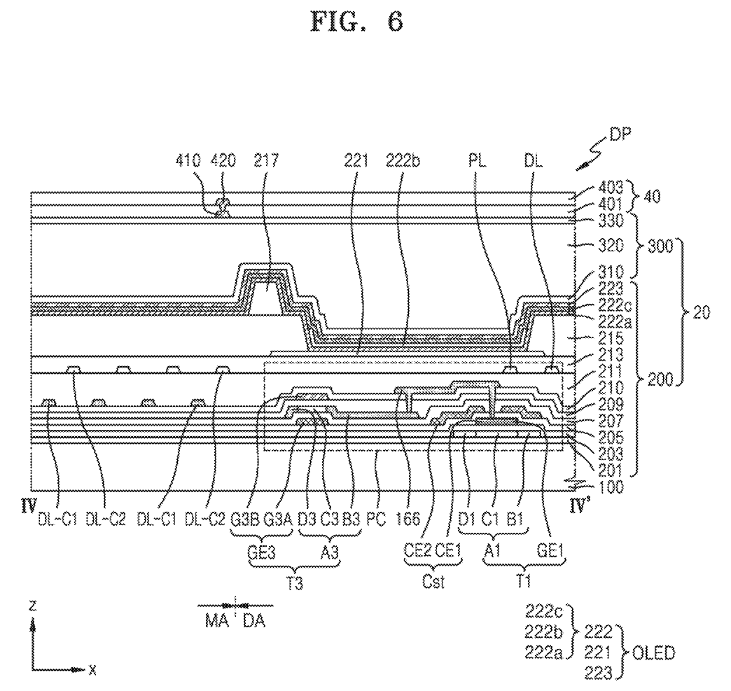

FIG. 6 is a schematic cross-sectional view of the display panel DP taken along the line IV-IV' of FIG. 5, according to some embodiments.

Referring to FIG. 6, the substrate 100 may include a glass material or polymer resins. According to some embodiments, the substrate 100 may have an alternate stack structure of a base layer including polymer resins and a barrier layer including an inorganic insulating material, such as silicon oxide or silicon nitride. The polymer resins may include polyether sulfone, polyarylate, polyether imide, polyethylene naphthalate, polyethylene terephthalate, polyphenylene sulfide, polyimide, polycarbonate, cellulose triacetate, or cellulose acetate propionate.

The pixel circuit PC may be formed on the substrate 100, and the light-emitting diode, for example, the organic light-emitting diode OLED, may be formed on the pixel circuit PC.

A buffer layer 201 may be formed between the substrate 100 and the pixel circuit PC. The buffer layer 201 may prevent or reduce penetration of contaminants or impurities into the pixel circuit PC. The buffer layer 201 may include an inorganic insulating material, such as silicon nitride, silicon oxynitride, and silicon oxide, and may include a single-layered or multi-layered structure including the inorganic insulating material described above.

The pixel circuit PC may include a plurality of transistors and a storage capacitor as described above with reference to FIGS. 4A or 4B. With respect to this aspect, FIG. 6 illustrates the first transistor T1, the third transistor T3, and the storage capacitor Cst.

The first transistor T1 may include a semiconductor layer (hereinafter, referred to as a first semiconductor layer A1) on the buffer layer 201 and a gate electrode (hereinafter, referred to as a first gate electrode GE1) overlapping a channel area C1 of the first semiconductor layer A1. The first semiconductor layer A1 may include a silicon-based semiconductor material, for example, polysilicon. The first semiconductor layer A1 may include the channel area C1 and a first area B1 and a second area D1 arranged at both sides of the channel area C1, respectively. The first area B1 and the second area D1 may include more highly concentrated impurities than the channel area C1, and any one of the first area B1 and the second area D1 may correspond to a source area, and the other may correspond to a drain area.

A first gate insulating layer 203 may be arranged between the first semiconductor layer A1 and the first gate electrode GE1. The first gate insulating layer 203 may include an inorganic insulating material, such as silicon oxide, silicon nitride, and silicon oxynitride, and may include a single-layered or multi-layered structure including the inorganic insulating material described above.

The first gate electrode GE1 may include a conductive material including Mo, Al, Cu, Ti, etc. and may include a single-layered or multi-layered structure including the material described above.

The storage capacitor Cst may include a lower electrode CE1 and an upper electrode CE2 overlapping each other. According to some embodiments, the lower electrode CE1 of the storage capacitor Cst may include the first gate electrode GE1. In other words, the first gate electrode GE1 may include the lower electrode CE1 of the storage capacitor Cst. For example, the first gate electrode GE1 and the lower electrode CE1 of the storage capacitor Cst may be integrally formed with each other.

A first interlayer insulating layer 205 may be arranged between the lower electrode CE1 and the upper electrode CE2 of the storage capacitor Cst. The first interlayer insulating layer 205 may include an inorganic insulating material, such as silicon oxide, silicon nitride, and silicon oxynitride, and may include a single-layered or multi-layered structure including the inorganic insulating material described above.

The upper electrode CE2 of the storage capacitor Cst may include a low-resistance conductive material, such as Mo, Al, Cu, and/or Ti, and may include a single-layered or multi-layered structure including the material described above.

A second interlayer insulating layer 207 may be arranged on the storage capacitor Cst. The second interlayer insulating layer 207 may include an inorganic insulating material, such as silicon oxide, silicon nitride, and silicon oxynitride, and may include a single-layered or multi-layered structure including the inorganic insulating material described above.

A semiconductor layer (hereinafter, referred to as a third semiconductor layer A3) of the third transistor T3 may be arranged on the second interlayer insulating layer 207. The third semiconductor layer A3 may include an oxide-based semiconductor material. For example, the third semiconductor layer A3 may include a Zn oxide-based material, for example, a Zn oxide, an In-Zn oxide, a Ga-In-Zn oxide, etc. According to some embodiments, the third semiconductor layer A3 may include a semiconductor including In-Ga-Zn-O (IGZO), In-Sn-Zn-O (ITZO), or In-Ga-Sn-Zn-O (IGTZO), in which a metal, such as In, Ga, or Sn, is included in ZnO.

The third semiconductor layer A3 may include a channel area C3 and a first area B3 and a second area D3 arranged at both sides of the channel area C3, respectively. Any one of the first area B3 and the second area D3 may correspond to a source area, and the other may correspond to a drain area.

The third transistor T3 may include a gate electrode (hereinafter, referred to as a third gate electrode GE3) overlapping the channel area C3 of the third semiconductor layer A3. The third gate electrode GE3 may have a dual gate structure including a lower gate electrode G3A arranged below the third semiconductor layer A3 and an upper gate electrode G3B arranged above the channel area C3.

The lower gate electrode G3A may be arranged on the same layer (for example, the first interlayer insulating layer 205) as the upper electrode CE2 of the storage capacitor Cst. The lower gate electrode G3A may include the same material as the upper electrode CE2 of the storage capacitor Cst.

The upper gate electrode G3B may be arranged above the third semiconductor layer A3 with a second gate insulating layer 209 therebetween. The second gate insulating layer 209 may include an inorganic insulating material, such as silicon oxide, silicon nitride, and silicon oxynitride, and may include a single-layered or multi-layered structure including the inorganic insulating material described above.

A third interlayer insulating layer 210 may be arranged on the upper gate electrode G3B. The third interlayer insulating layer 210 may include an inorganic insulating material, such as silicon oxynitride, and may include a single-layered or multi-layered structure including the inorganic insulating material described above.

FIG. 6 illustrates the first transistor T1 and the third transistor T3 described with reference to FIG. 4A and illustrates that the first semiconductor layer A1 and the third semiconductor layer A3 are arranged on different layers. According to some embodiments, the second, fifth, sixth, and seventh transistors T2, T5, T6, and T7 described with reference to FIG. 4A may have the same structure as the first transistor T1 described with reference to FIG. 6. For example, each of the second, fifth, sixth, and seventh transistors T2, T5, T6, and T7 (see FIG. 4A) may include a semiconductor layer arranged on the same layer (for example, the buffer layer 201) as the first semiconductor layer A1 of the first transistor T1 and a gate electrode arranged on the same layer (for example, the first gate insulating layer 203) as the first gate electrode GE1 of the first transistor T1. The semiconductor layers of the second, fifth, sixth, and seventh transistors T2, T5, T6, and T7 (see FIG. 4A) may be integrally connected to the first semiconductor layer A1.

FIG. 6 illustrates that the first semiconductor layer A1 and the third semiconductor layer A3 are arranged on different layers, but the disclosure is not limited thereto. According to some embodiments, as illustrated in FIG. 4B, when the first transistor T1 and the third transistor T3 are the same NMOS transistors, the first semiconductor layer A1 may be arranged on the same layer as the third semiconductor layer A3, for example, on the second interlayer insulating layer 207, and the semiconductor layer of the fifth transistor T5 of FIG. 4B may include polysilicon and may be arranged on the buffer layer 201. Hereinafter, for convenience of explanation, the case where the first semiconductor layer A1 of the first transistor T1 includes polysilicon and the third semiconductor layer A3 of the third transistor T3 includes an oxide semiconductor is described.

The first transistor T1 and the third transistor T3 may be electrically connected to each other through a node connection line 166. The node connection line 166 may be arranged on the third interlayer insulating layer 210. A side of the node connection line 166 may be connected to the first gate electrode GE1 of the first transistor T1, and the other side of the node connection line 166 may be connected to the third semiconductor layer A3 of the third transistor T3.

The node connection line 166 may include Al, Cu, and/or Ti and may include a single layer or layers including the material described above. For example, the node connection line 166 may have a tri-layered structure of a Ti layer/an Al layer/a Ti layer.

A first organic insulating layer 211 may be arranged on the node connection line 166. The first organic insulating layer 211 may include an organic insulating material. The organic insulating material may include acryl, benzocyclobutene (BCB), polyimide, or hexamethyldisiloxane (HMDSO).

The data line DL and the driving voltage line PL may be arranged on the first organic insulating layer 211 and may be covered by a second organic insulating layer 213. The data line DL and the driving voltage line PL may include Al, Cu, and/or Ti and may include a single layer or layers including the material described above. For example, the data line DL and the driving voltage line PL may have a tri-layered structure of a Ti layer/an Al layer/a Ti layer.

The second organic insulating layer 213 may include an organic insulating material, such as acryl, BCB, polyimide, and/or HMDSO. FIG. 6 illustrates that the data line DL and the driving voltage line PL may be formed on the first organic insulating layer 211. However, the disclosure is not limited thereto. According to some embodiments, any one of the data line DL and the driving voltage line PL may be arranged on the same layer as the node connection line 166.

The light-emitting diode, for example, the organic light-emitting diode OLED, may be arranged on the second organic insulating layer 213.

A pixel electrode 221 of the organic light-emitting diode OLED may include a reflective layer including Ag, Mg, Al, Pt, Pd, Au, Ni, Nd, Ir, Cr, or a compound thereof. According to some embodiments, the pixel electrode 221 may further include a conductive oxide layer above and/or below the reflective layer described above. The conductive oxide layer may include indium tin oxide (ITO), indium zinc oxide (IZO), zinc oxide (ZnO), indium oxide (In₂O₃), indium gallium oxide (IGO), and/or aluminum zinc oxide (AZO). According to some embodiments, the pixel electrode 221 may have a tri-layered structure of ITO/Ag/ITO layers.

A bank layer 215 may be arranged on the pixel electrode 221. The bank layer 215 may include an opening overlapping the pixel electrode 221 and may cover an edge of the pixel electrode 221. The bank layer 215 may include an organic insulating material.

An intermediate layer 222 may include an emission layer 222b. The intermediate layer 222 may include a first functional layer 222a arranged below the emission layer 222b and/or a second functional layer 222c arranged above the emission layer 222b. The emission layer 222b may include a high molecular-weight or low molecular-weight organic material emitting light of a certain color. The first functional layer 221a may include a hole transport layer and/or a hole injection layer. The second functional layer 222c may include an electron transport layer and/or an electron injection layer. The first functional layer 222a and the second functional layer 222c may include an organic material.

An opposite electrode 223 may include a conductive material having a low work function. For example, the opposite electrode 223 may include a transparent (or transflective) layer including Ag, Mg, Al, Pt, Pd, Au, Ni, Nd, Ir, Cr, Li, Ca, or an alloy thereof. Alternatively, the opposite electrode 223 may further include a layer, such as ITO, IZO, ZnO, or In₂O₃, on the transparent (or transflective) layer including the material described above.

The emission layer 222b may be formed in the display area DA to overlap the pixel electrode 221 through the opening of the bank layer 215. However, the first functional layer 222a, the second functional layer 222c, and the opposite electrode 223 may extend to be located not only in the display area DA, but also in the non-display area MA.

A spacer 217 may be formed on the bank layer 215. The spacer 217 may be formed together with the bank layer 215 by the same process or may be separately formed from the bank layer 215 by a separate process. According to some embodiments, the spacer 217 may include an organic insulating material such as polyimide.

The organic light-emitting diode 220 may be covered by an encapsulation layer 300. The encapsulation layer 300 may include at least one organic encapsulation layer and at least one inorganic encapsulation layer. According to some embodiments, FIG. 6 illustrates that the encapsulation layer 300 may include a first inorganic encapsulation layer 310, a second inorganic encapsulation layer 330, and an organic encapsulation layer 320 therebetween.

The first and second inorganic encapsulation layers 310 and 330 may include one or more inorganic materials from among aluminum oxide (Al₂O₃), titanium oxide (TiO), tantalum oxide (TA₂O₅), hafnium oxide (HfO₂), zinc oxide (ZnO), silicon oxide (SiOₓ), silicon nitride (SiNₓ), and silicon oxynitride (SiON). The first and second inorganic encapsulation layers 310 and 330 may include a layer or layers including the material described above. The organic encapsulation layer 320 may include a polymer-based material. The polymer-based material may include acryl-based resins, epoxy-based resins, polyimide, polyethylene, etc. According to some embodiments, the organic encapsulation layer 320 may include acrylate.

Thicknesses of the first and second inorganic encapsulation layers 310 and 330 may be different from each other. The thickness of the first inorganic encapsulation layer 310 may be greater than the thickness of the second inorganic encapsulation layer 330. Alternatively, the thickness of the second inorganic encapsulation layer 330 may be greater than the thickness of the first inorganic encapsulation layer 310, or the thicknesses of the first and second inorganic encapsulation layer 310 and 330 may be the same as each other.

The input sensing layer 40 may be arranged on the encapsulation layer 300. The input sensing layer 40 may include a first touch metal layer 410, a second touch metal layer 420, a first touch insulating layer 401, and a second touch insulating layer 403.

The first touch metal layer 410 and the second touch metal layer 420 may form an input sensing sensor. For example, the second touch metal layer 420 may include mesh-shaped electrode patterns, and the first touch metal layer 410 may include connection patterns electrically connecting the electrode patterns. Each of the first touch metal layer 410 and the second touch metal layer 420 may include Al, Cu, and/or Ti and may include a layer or layers including the materials described above. For example, each of the first conductive layer 402 and the second conductive layer 404 may have a tri-layered structure of a Ti layer/an Al layer/a Ti layer.

The first touch insulating layer 401 may be arranged between the first touch metal layer 410 and the second touch metal layer 420. The second touch insulating layer 403 may be arranged on the first touch insulating layer 401 to cover the second touch metal layer 420. Each of the first touch insulating layer 401 and the second touch insulating layer 403 may include an inorganic insulating material and/or an organic insulating material.

The display panel DP may include the substrate 100, the image generation layer 20, and the input sensing layer 40. The optical functional layer 50, the cover window 60, etc. may further be arranged on the input sensing layer 40 as described above with reference to FIG. 2.

Referring to the non-display area MA of FIG. 6, the non-display area MA may include a line bypass region crossed by the bypass portions DL-C1 and DL-C2 of the data lines DL described above with reference to FIG. 5.

The bypass portions DL-C1 and DL-C2 of the data lines DL may be arranged on different layers from each other. Any one of the bypass portions DL-C1 and DL-C2 of the data lines DL adjacent to each other may be arranged on the third interlayer insulating layer 210, and the other may be arranged on the first organic insulating layer 211. The bypass portions DL-C1 and DL-C2 of the data lines DL may be alternately arranged with an insulating layer (for example, a first organic insulating layer 211) therebetween.

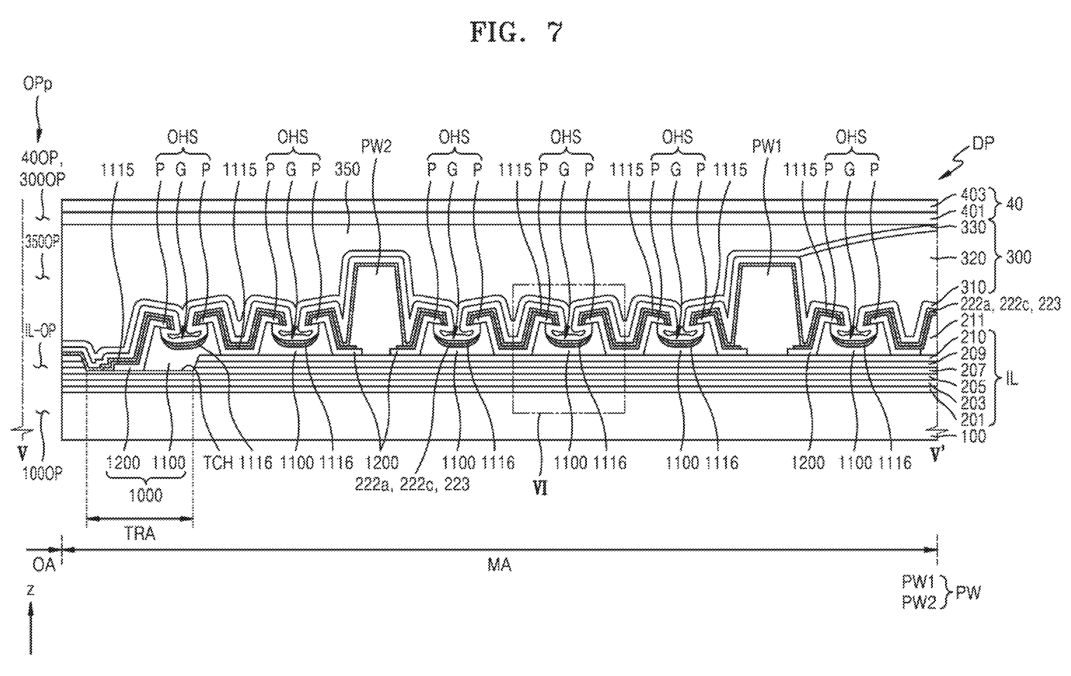

FIG. 7 is a schematic cross-sectional view of the display panel DP taken along the line V-V' of FIG. 5, according to some embodiments.

Referring to FIGS. 5 and 7 together, the display panel DP may include the panel opening OPp corresponding to the opening area OA, and in the non-display area MA, structures to prevent or reduce transferring of cracks and/or moisture or contaminant permeation may be provided. The panel opening OPp may be formed by passing through a plurality of layers included in the display panel DP. With respect to this aspect, FIG. 7 illustrates an opening 100OP passing through the substrate 100, an opening IL-OP passing through an inorganic insulating structure IL from an upper surface thereof to a lower surface thereof, an opening 300OP passing through each of the first and second inorganic encapsulation layers 310 and 330, an opening 350OP passing through a planarization layer 350, and an opening 40OP passing through each of the first and second touch insulating layers 401 and 403. The inorganic insulating structure IL may include a stack structure including a plurality of inorganic insulating layers. According to some embodiments, the organic insulating structure IL may include the buffer layer 201, the first gate insulating layer 203, the first interlayer insulating layer 205, the second interlayer insulating layer 207, the second gate insulating layer 209, and the third interlayer insulating layer 210 as illustrated in FIG. 7.

Referring to FIGS. 5 and 7, overhang structures OHS and the partition walls PW may be arranged in the non-display area MA. The encapsulation layer 300 may extend to the non-display area MA and may overlap the overhang structures OHS and the partition walls PW. The partition walls PW may include organic layers having a step difference from a peripheral area and may include the first partition wall PW1 and the second partition wall PW2 apart from each other by a certain distance.

The overhang structures OHS may be arranged to be apart from each other in the non-display area MA. According to some embodiments, at least one overhang structure OHS may be arranged between the first partition wall PW1 and the display area DA, a plurality of overhang structures OHS (for example, three overhang structures OHS) may be arranged between the first partition wall PW1 and the second partition wall PW2, and a plurality of overhang structures (for example, two overhang structures OHS) may be arranged between the second partition wall PW2 and the opening 100OP of the substrate 100. According to some embodiments, one or more partition walls (hereinafter, referred to as a third partition wall) may further be arranged between the first partition wall PW1 and the second partition wall PW2, one or more overhang structures OHS may be arranged between the first partition wall PW1 and the third partition wall, and one or more overhang structures OHS may be arranged between the third partition wall and the second partition wall PW2. Hereinafter, descriptions are given based on the structure illustrated in FIG. 7, for convenience of explanation.

Each of the partition walls PW and each of the overhang structures OHS may have a closed-loop shape surrounding the opening area OA. That "A" has a closed-loop shape surrounding the opening area OA in a plan view may denote that "A" has a closed-loop shape surrounding the opening 100OP of the substrate 100 in a plan view.

The overhang structure OHS may be defined in a multi-layer 1000 including a first layer 1100 and a second layer 1200 having different materials from each other. The second layer 1200 may be arranged on the first layer 1100 and may have a less thickness than the first layer 1100. The overhang structure OHS may include a groove G defined in the first layer 1100 and an overhang portion P hanging over the groove G to have an eaves structure. According to some embodiments, the overhang structure OHS may include the groove G defined in the first layer 1100 and two overhang portions P hanging over the groove G toward each other as illustrated in FIG. 7.

The first layer 1100 may include an insulating material. According to some embodiments, the first layer 1100 may include an organic insulating material. For example, the material of the first layer 1100 may be the same as the material of the first organic insulating layer 211 described with reference to FIG. 6. The groove G may be a portion recessed in a thickness direction (for example, a z direction) of the first layer 1100, and the depth of the groove G may be less than the depth of the first layer 1100.

The first layers 1100 may be arranged to be apart from each other in the non-display area MA. Like the overhang structure OHS, the first layer 1100 may have a closed-loop shape surrounding the opening area OA and/or the opening 100OP of the substrate 100 in a plan view.

The second layer 1200 may include a conductive material. According to some embodiments, the second layer 1200 may include a metal layer including a metal material, such as Mo, Al, Cu, Ti, etc. The second layer 1200 may include a single-layered or a multi-layered structure including the material described above. According to some embodiments, the second layer 1200 may have a tri-layered stack structure of Ti/Al/Ti layers. For example, the second layer 1200 may be formed in the same process as the data line DL and/or the driving voltage line PL described with reference to FIG. 6 and may include the same material as the data line DL and/or the driving voltage line PL.

Two second layers 1200 may be arranged at both sides of the groove G. The overhang portion P of each of the two second layers 1200 may hang over the groove G toward each other to have an eaves shape. For example, the two overhang portions P arranged at both sides of the groove G may extend toward each other with a gap maintained therebetween.

The second layer 1200 arranged on any one first layer 1100 may be integrally connected to the second layer 1200 arranged on the other first layer 1100 arranged to be adjacent to the one first layer 1100. In other words, one second layer 1200 may extend onto the two adjacent first layers 1100 and may include the overhang portions P extending to hang over the grooves G of the two first layers 1100. The second layer 1200 described above may be in contact with an upper surface of an uppermost layer (for example, an inorganic insulating layer arranged right below the first layer 1100) exposed between the two adjacent first layers 1100.

A protective layer 1115 may be arranged on the overhang portion P and may protect the overhang portion P. The protective layer 1115 may be arranged on an upper surface and a side surface of the overhang portion P. The protective layer 1115 may include a conductive material. According to some embodiments, the protective layer 1115 may include the same material as the pixel electrode 221 described above with reference to FIG. 6. The protective layer 1115 may have a tri-layered structure of ITO/Ag/ITO layers. In a process of forming the protective layer 1115, a layer (hereinafter, referred to as a protective material layer 1116) including the same material as the protective layer 1115 may be provided on a bottom surface of the groove G.

Layers including an organic material from among the layers included in the organic light-emitting diode OLED (see FIG. 6), for example, the first functional layer 222a and/or the second functional layer 222c, may be formed not only in the display area DA, but also in the non-display area MA. According to a comparative embodiment, a first functional layer and a second functional layer that are continually formed in a non-display area may provide a path of moisture permeation through a panel opening, which may lead to damage to an organic light-emitting diode.

However, according to some embodiments, the first functional layer 222a and/or the second functional layer 222c including the organic material, from among the layers included in the organic light-emitting diode, may be separated into a plurality of portions by the overhang structure OHS in the non-display area MA. Thus, a moisture proceeding path through the opening area OA may be blocked, to prevent or reduce damage to the organic light-emitting diode OLED (see FIG. 6). Similarly, the opposite electrode 223 may also be separated into a plurality of portions by the overhang structure OHS in the non-display area MA. With respect to this aspect, FIG. 7 illustrates that each of the first functional layer 222a, the second functional layer 222c, and the opposite electrode 223 is separated into the plurality of portions in the non-display area MA. Each of the first functional layer 222a, the second functional layer 222c, and the opposite electrode 223 may be separated into a portion arranged on the overhang portion P and a portion arranged on the bottom surface of the groove G.

The non-display area MA may include a trench area TRA relatively close to the opening area OA. The trench area TRA may be where a trench TCH defined in the inorganic insulating structure IL is arranged, and the trench TCH may have a shape recessed in a thickness direction of the inorganic insulating structure IL. The display panel DP may include the trench TCH defined in the inorganic insulating structure IL, and thus, it may be possible to prevent or reduce transferring of shocks (for example, shocks occurring in a process of forming the panel opening OPp), which may occur during a manufacturing process of the display panel DP, and the cracks caused by the shocks, to the display area DA.

The trench TCH may be arranged between the opening area OA and a partition wall arranged to be the closest to the opening area OA from among the partition walls. With respect to this aspect, FIG. 7 illustrates that the trench TCH is arranged between the second partition wall PW2 and the opening area OA. The width of the trench TCH may be greater than the width of the groove G of the first layer 1100. The depth of the trench TCH may be less than the sum of the depths included in the inorganic insulating structure IL. According to some embodiments, FIG. 7 illustrates that the trench TCH crosses an upper surface and a lower surface of the third interlayer insulating layer 210, an upper surface and a lower surface of the second gate insulating layer 209, and an upper surface of the second interlayer insulating layer 207. However, the disclosure is not limited thereto.

One of the overhang structures OHS may overlap the trench TCH. For example, the overhang structure arranged to be the closest to the opening area OA from among the overhang structures OHS, may overlap the trench TCH.

According to some embodiments, the first layer 1100 may be arranged at any one of peripheral portions at both sides of the trench TCH. The trench TCH may include a first peripheral portion relatively close the opening area OA and a second peripheral portion that is at the opposite side to the first peripheral portion, and the first layer 1100 may be arranged at the second peripheral portion, which is relatively farther from the opening area OA of the both peripheral portions of the trench TCH. The first layer 1100 may cover a step difference of the second peripheral portion at one side of the trench TCH.

The second layer 1200 on the first layer 1100 overlapping the trench TCH may include the overhang portion P extending toward the groove G, and a portion of the second layer 1200, which is at the opposite side to the overhang portion P, may cross a side surface of the first layer 1100 and extend onto a bottom surface of the trench TCH. The portion of the second layer 1200 described above may be in direct contact with the bottom surface of the trench TCH.

The encapsulation layer 300 may extend not only to the display area DA (see FIG. 5), but also to the non-display area MA. Each of the first inorganic encapsulation layer 310 and the second inorganic encapsulation layer 330 may be arranged on the trench TCH, the overhang structure OHS, the first partition wall PW1, and the second partition wall PW2. Each of the first inorganic encapsulation layer 310 and the second inorganic encapsulation layer 330 may cross the trench area TRA and extend toward the opening area OA. The first inorganic encapsulation layer 310 may continually cover an upper surface, a side surface, and a bottom surface of the overhang portion P and an inner surface of the first layer 1100 defining the groove G.

The partition walls PW may have a step difference from a peripheral area and may control flowing of a monomer when the organic encapsulation layer 320 is formed. It is illustrated that the organic encapsulation layer 320 overlaps the overhang structure OHS between the first partition wall PW1 and the display area DA (see FIG. 5). The overhang structure OHS between the first partition wall PW1 and the display area DA (see FIG. 5) may overlap the first inorganic encapsulation layer 310, the organic encapsulation layer 320, and the second inorganic encapsulation layer 330.

The second inorganic encapsulation layer 330 may be in direct contact with the first inorganic encapsulation layer 310 in a region of the non-display area MA. For example, the second inorganic encapsulation layer 330 may be in direct contact with the first inorganic encapsulation layer 310 between the partition wall and the opening area OA. According to some embodiments, as illustrated in FIG. 7, above the overhang structures OHS between the first partition wall PW1 and the second partition wall PW2, the overhang structures OHS between the second partition wall PW2 and the opening area OA, and the trench TCH, a portion of the second inorganic encapsulation layer 330 may be in direct contact with a portion of the first inorganic encapsulation layer 310.

Each of the partition walls PW may be arranged between the overhang structures OHS adjacent to each other. The first partition wall PW1 may cover an end of each of the second layers 1200 arranged at both sides of the first partition wall PW1 and extending onto upper surfaces of the inorganic insulating structures IL and an end of the protective layer 115 arranged on each of the second layers 1200. The second partition wall PW2 may cover an end of each of the second layers 1200 arranged at both sides of the second partition wall PW2 and extending onto upper surfaces of the inorganic insulating structures IL and an end of the protective layer 115 arranged on each of the second layers 1200. Each of the partition walls PW may have a closed-curve shape surrounding the opening area OA in a plan view. According to some embodiments, the width of the first partition wall PW1 may be greater than the width of the second partition wall PW2.

The planarization layer 350 may be arranged on the encapsulation layer 300 in the non-display area MA. The planarization layer 350 may cover the structures provided in the non-display area MA, for example, the partition walls PW, the overhang structures OHS, and the trench TCH, to provide a flat upper surface. The planarization layer 350 may include an organic insulating material. The organic insulating material may include acryl, BCB, polyimide, or HMDSO. The first touch insulating layer 401 and the second touch insulating layer 403 of the input sensing layer 40 may be arranged on the planarization layer 350.

Upper surfaces of the first partition wall PW1 and the second partition wall PW2 may protrude from a peripheral area, for example, upper surfaces of the overhang structures OHS, in a thickness direction (for example, a z direction). Layers formed on the partition walls PW, for example, the first functional layer 222a, the second functional layer 222c, the opposite electrode 223, the first inorganic encapsulation layer 310, and the second inorganic encapsulation layer 330, may have shapes corresponding to the partition walls PW. When a material for forming the planarization layer 350 is applied to form the planarization layer 350, some regions may not be filled with the material, due to a sharp step difference due to the partition walls PW. Thus, as illustrated in FIG. 5, the partition walls PW may have the concave portions which may help distribution of the material in the planarization layer 350 so that the space between the partition walls PW may be relatively uniformly filled with the material for forming the planarization layer 350.

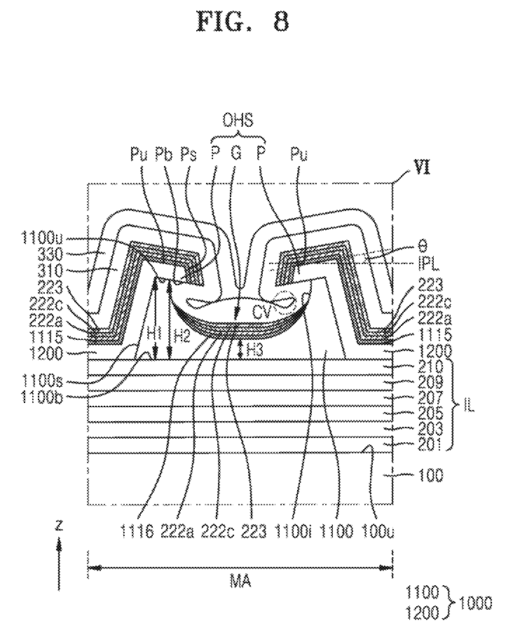

FIG. 8 is an enlarged schematic cross-sectional view of a portion of the display panel DP, the portion corresponding to region VI of FIG. 7, according to some embodiments.

Referring to FIG. 8, the overhang structure OHS may be arranged on the inorganic insulating structure IL. The overhang structure OHS may be defined in the multi-layer 1000, and the multi-layer 1000 may include the first layer 1100 and the second layer 1200 including different materials from each other and having different thicknesses from each other. The first layer 1100 may include an insulating material, and the second layer 1200 may include a conductive material. According to some embodiments, the first layer 1100 may include an organic insulating material, for example, acryl, BCB, polyimide, or HMDSO, etc., and may include a layer or layers including the material described above. The second layer 1200 may include Al, Cu, and/or Ti and may include a layer or layers including the material described above.

The first layer 1100 may be arranged on the uppermost layer of the inorganic insulating layer IL, for example, the third interlayer insulating layer 210. The first layer 1110 may include a lower surface 1110b in contact with an upper surface of the third interlayer insulating layer 210, an inner surface 1100i defining the groove G, a side surface 1100s tapered in a forward direction toward the upper surface of the third interlayer insulating layer 210, and an upper surface 1100u between the side surface 1100s and the inner surface 1100i.

The upper surface 1100u of the first layer 1100 may be downwardly tilted from the outside to the inside where the groove G is provided. Thus, a first vertical distance H1 from an upper surface of the inorganic insulating structure IL to a point where the side surface 1100s of the first layer 1100 and the upper surface 1100u of the first layer 1100 meet each other, may be greater than a second vertical distance H2 from the upper surface of the inorganic insulating layer IL to a point where the inner surface 1100i of the first layer 1100 and a bottom surface of the second layer 1200 meet each other. The depth of the groove G may be less than the thickness of the first layer 1100, and thus, a third vertical distance H3 from the upper surface of the inorganic insulating layer IL to a point corresponding to the center of the groove G may be less than the second vertical distance H2.

Two second layers 1200 may be arranged at both sides of the groove G in the first layer 1100. Each of the second layers 1200 arranged at both sides of the groove G may include the overhang portion P hanging over the groove G.

The second layer 1200 arranged at a side (for example, the left side) of the groove G may include the overhang portion P extending (or protruding) toward the groove G from a point where a lower surface of the second layer 1200 meets the inner surface 1100i of the first layer 1100 defining the groove G. Similarly, the second layer 1200 arranged at the other side (for example, the right side) of the groove G may include the overhang portion P extending (or protruding) toward the groove from a point where the lower surface of the second layer 1200 meets the inner surface 1100i of the first layer 1100 defining the groove G.

Each of the two second layers 1200 may cross the both side surfaces 1100s of the first layer 1100 and extend onto the upper surface of the inorganic insulating structure IL. Each second layer 1200 may be in direct contact with the side surface 1100s of the first layer 1100 and the upper surface of the inorganic insulating structure IL.

An upper surface Pu of the overhang portion P may be arranged on a virtual plane IPL parallel to an upper surface 100u of the substrate 100 or on another plane different from the virtual plane IPL. A first angle θ between the virtual plane IPL parallel to the upper surface 100u of the substrate 100 and the upper surface Pu of each overhang portion P may have a range of 0° to 40° (or about 40°) (0°≤ θ ≤ 40°).

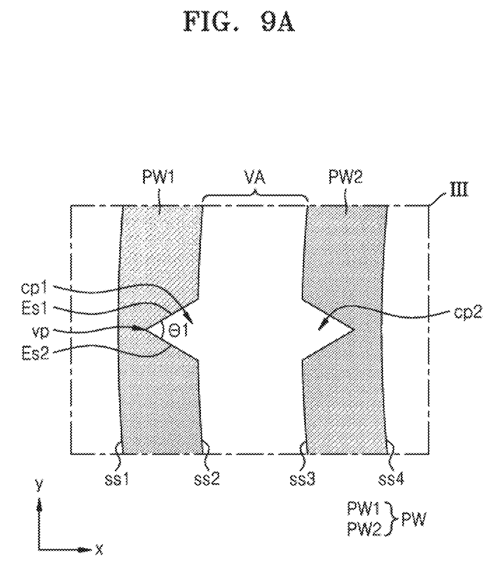

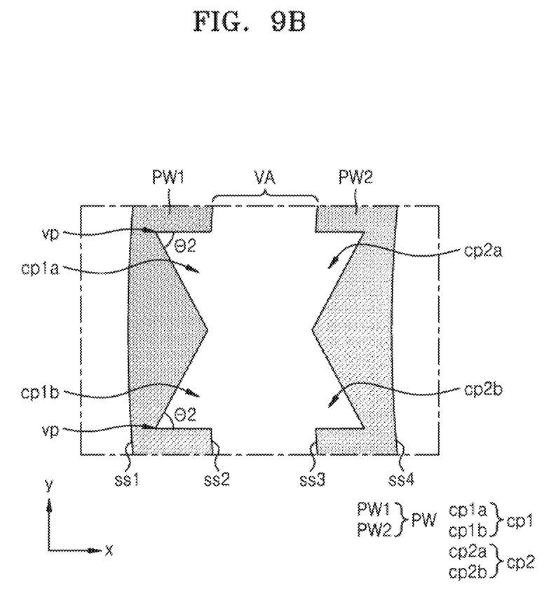

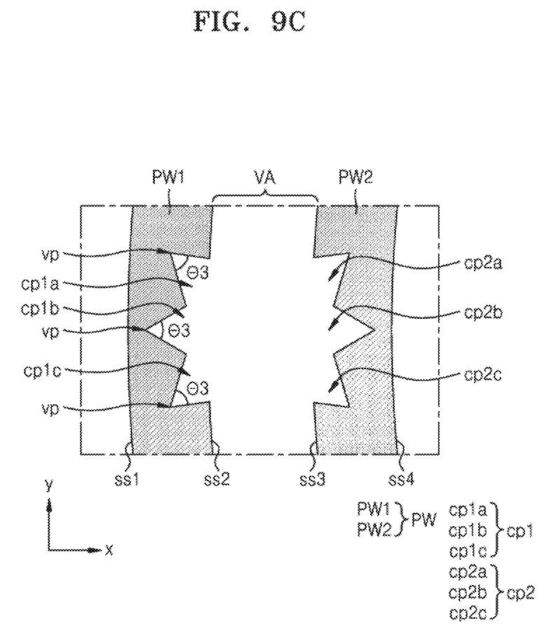

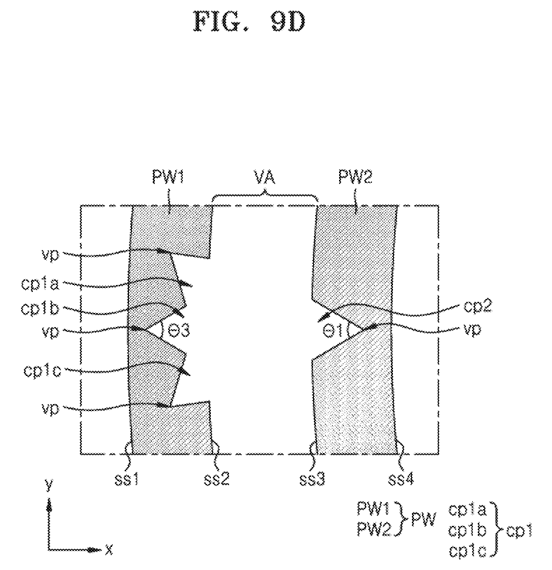

According to some embodiments, each of the second layers 1200 may be downwardly tilted toward the groove G. For example, the first angle θ between the virtual plane IPL parallel to the upper surface 100u of the substrate 100 and the upper surface Pu of each overhang portion P may be greater than 0° (or about 0°) and equal to or less than 40° (or about 40°) (0°< θ ≤ 40°). For example, as illustrated in FIG. 8, the first angle θ may be greater than 0° (or about 0°) and equal to or less than 30° (or about 30°) (0°< θ ≤ 30°). According to some embodiments, the first angle θ may be 0° (or about 0°). For example, as illustrated in FIG. 9, the upper surface Pu of the overhang portion P may be arranged on the virtual plane IPL parallel to the upper surface 100u of the substrate 100.

When the first angle θ has a range that is greater than 0° (or about 0°) and equal to or less than 40° (or about 40°) (0°< θ ≤ 40°), the separation of the overhang portion P from the first layer 1100 with the overhang portion P being lifted from the first layer 1100 may be prevented or reduced. By preventing or reducing the lifting of the overhang portion P, detachment of the first inorganic encapsulation layer 310 and the second inorganic encapsulation layer 330 may be prevented or reduced.

The protective layer 1115 may be arranged on the second layer 1200. The protective layer 1115 may be arranged on the overhang portion P and may be in direct contact with the overhang portion P. The protective layer 1115 may be arranged on the upper surface Pu and a side surface Ps of the overhang portion P. The protective layer 1115 may extend to overlap the side surface 1100s of the first layer 1100 and the upper surface of the inorganic insulating structure IL. The protective layer 1115 may prevent or reduce damage to the overhang portion P during a manufacturing process of the display panel 10 (see FIG. 8), thereby preventing or reducing a decrease in the length (for example, the eaves length) of the overhang portion P.

The protective layer 1115 may include a conductive material, for example, the same material as the pixel electrode 221 (see FIG. 6). The protective layer 1115 may be formed by a deposition process, and a material included in the protective layer 1115 may be deposited in the groove G, so that the protective material layer 1116 the same as the protective layer 1115 may be provided on the bottom surface of the groove G, as illustrated in FIG. 8.

As described above with reference to FIG. 7, the organic material layer included in the organic light-emitting diode OLED, for example, the first functional layer 222a and the second functional layer 222c, may be separated into a plurality of portions by the overhang structure OHS. As illustrated in FIG. 8, each of the first functional layer 222a and the second functional layer 222c may include portions arranged on the overhang portions P and a portion arranged in the groove G. A portion of each of the first functional layer 222a and the second functional layer 222c may be arranged on the protective layer 1115 above the overhang portion P, and another portion of each of the first functional layer 222a and the second functional layer 222c may be arranged on the protective material layer 1116 arranged on the bottom surface of the groove G.

Similarly, the opposite electrode 223 may be separated into a plurality of portions. As illustrated in FIG. 8, the opposite electrode 223 may include portions arranged on the overhang portions P and a portion arranged in the groove G. A portion of the opposite electrode 223 may be arranged on the second functional layer 222c above the overhang portion P, and another portion of the opposite electrode 223 may be arranged on the second functional layer 222c arranged on the bottom surface of the groove G.

The first inorganic encapsulation layer 310 may have excellent step coverage, and thus, may continually extend rather than being separated by the overhang structure OHS. For example, the first inorganic encapsulation layer 310 may continually extend to overlap the upper surface Pu, the side surface Ps, and a bottom surface Pb of the overhang portion P. According to some embodiments, the upper surfaces of the first inorganic encapsulation layer 310 may be in contact with each other between the overhang portions P adjacent to each other. In this case, a cavity cv may be provided in a cross-sectional view, as illustrated in FIG. 8. According to some embodiments, according to the thickness of the first inorganic encapsulation layer 310 ad/or a gap between the overhang portions P, the cavity cv may not be provided.

The second inorganic encapsulation layer 330 may also have excellent step coverage, and thus, may continually extend rather than being separated by the overhang structure OHS. The second inorganic encapsulation layer 330 may be in direct contact with the first inorganic encapsulation layer 310 above some overhang structures OHS from among the overhang structures OHS illustrated in FIG. 7.

FIG. 9A is an enlarged schematic plan view of a portion of the display panel DP, the portion corresponding to region III of FIG. 5, according to some embodiments. FIGS. 9B to 9D are each a plan view of a portion of the display panel DP according to some embodiments. FIGS. 9B to 9D are enlarged schematic views of a portion corresponding to region III of FIG. 5.

Referring to FIG. 9A, the partition walls PW may be arranged in the non-display area MA (see FIG. 5). The partition walls PW may include the first partition wall PW1 and the second partition wall PW2. The first partition wall PW1 and the second partition wall PW2 may have a closed-loop structure surrounding the opening area OA (see FIG. 5) and may be apart from each other by a certain distance. The first partition wall PW1 may be arranged to be close to the display area DA (see FIG. 5), and the second partition wall PW2 may be arranged to be close to the opening area OA. According to some embodiments, the first partition wall PW1 and the second partition wall PW2 may be concentric circles having different diameters.

The first partition wall PW1 and the second partition wall PW2 may protrude in a thickness direction of the display panel DP, and the valley area VA having a bottom surface at a lower level than an upper surface of the first partition wall PW1 and an upper surface of the second partition wall PW2 may be defined between the first partition wall PW1 and the second partition wall PW2.

The first partition wall PW1 may include a first side surface ss1 and a second side surface ss2 opposite to each other. The first side surface ss1 and the second side surface ss2 may be connected to the upper surface of the first partition wall PW1. The second partition wall PW2 may include a third side surface ss3 and a fourth side surface ss4 opposite to each other. The third side surface ss3 and the fourth side surface ss4 may be connected to the upper surface of the second partition wall PW2. The second surface ss2 of the first partition wall PW1 may be a surface toward the second partition wall PW2, and the third side surface ss3 of the second partition wall PW2 may be a surface toward the first partition wall PW1. The second side surface ss2 of the first partition wall PW1, the third side surface ss3 of the second partition wall PW2, and an exposed area between the first partition wall PW1 and the second partition wall PW2 may define the valley area VA.

As illustrated in FIG. 9A, a first concave portion cp1 may have one vertex vp at which two edges Es1 and ES2 extending in different directions in a plan view meet each other. For example, the first concave portion cp1 may have a first edge Es1 and a second edge Es2 connected to the second side surface ss2, and the first edge Es1 and the second edge Es2 may meet each other at the vertex vp. That is, the first concave portion cp1 may have a triangular (or an approximately triangular) shape connected to the valley area VA in a plan view. The first edge Es1 and the second edge Es2 may form a first angle θ1, and the first angle θ1 may be less than or equal to 90° (or about 90°). When the first angle θ1 is 70° (or about 70°) to 90° (or about 90°), a material for forming the planarization layer 350 may relatively more uniformly fill the valley area VA, and when the first angle θ1 is in different ranges, a portion of the valley area VA may not be filled with the material for forming the planarization layer 350.

The first partition wall PW1 may have the first concave portion cp1 on the second side surface ss2, the first concave portion cp1 being open toward the second partition wall PW2, and the second partition wall PW2 may have a second concave portion cp2 on the third side surface ss3, the second concave portion cp2 being open toward the first partition wall PW1. The first concave portioncp1 and the second concave portion cp2 may be arranged to face each other (e.g., arranged in alignment with each other). Here, that the first concave portion cp1 and the second concave portioncp2 are arranged to face each other may denote that the second concave portion cp2 is arranged to be adjacent to the first concave portion cp1 to correspond to the first concave portion cp1. According to some embodiments, the first concave portion cp1 and the second concave portion cp2 may have an axially symmetrical (or approximately symmetrical) shape with respect to a virtual line extending along the center of the valley area VA. The first concave portion cp1 and the second concave portion cp2 arranged to face each other may be connected to the valley area VA and may have a diamond (or approximately diamond) shape in a plan view.

Each of the first concave portion cp1 and the second concave portion cp2 may have two or more vertices vp at which two edges extending in different directions intersect in a plan view. FIG. 9B illustrates a case where each of the first concave portion cp1 and the second concave portion cp2 has two vertices vp, and FIG. 9C illustrates a case where each of the first concave portion cp1 and the second concave portion cp2 has three vertices vp.

First, referring to FIG. 9B, the first concave portion cp1 may have a first sub-concave portion cp1a and a second sub-concave portion cp1b having a triangular (or approximately triangular) shape in a plan view. The second concave portion cp2 may have a third sub-concave portion cp2a and a fourth sub-concave portion cp2b having a triangular (or approximately triangular) shape in a plan view. The first sub-concave portion cp1a and the second sub-concave portion cp1b may be continually arranged along the second side surface ss2 of the first partition wall PW1. Likewise, the third sub-concave portion cp2a and the fourth sub-concave portion cp2b may be continually arranged along the third side surface ss3 of the second partition wall PW2.

Two edges defining the first sub-concave portion cp1a and two edges defining the second sub-concave portion cp1b in a plan view may each form a second angle θ2, and the second angle θ2 may be less than or equal to 90°. When the second angle θ2 is 50° (or about 50°) to 90° (or about 90°), a material for forming the planarization layer 350 may relatively more uniformly fill the valley area VA, and in different ranges, a portion of the valley area VA may not be filled with the material for forming the planarization layer 350. The first concave portion cp1 and the second concave portion cp2 may be arranged to face each other and may have an axially symmetrical (or approximately symmetrical) shape with respect to a virtual line extending along the center of the valley area VA. The first concave portion cp1 and the second concave portion cp2 arranged to face each other may be connected to the valley area VA and may have a star (or approximately star) shape having four horns in a plan view.

Referring to FIG. 9C, each of the first concave portion cp1 and the second concave portion cp2 may have three vertices vp. For example, the first concave portion cp1 may include a first sub-concave portion cp1a, a second sub-concave portion cp1b, and a fifth sub-concave portion cp1c having a triangular (or approximately triangular) shape in a plan view. The second concave portion cp2 may include a third sub-concave portion cp2a, a fourth sub-concave portion cp2b, and a sixth sub-concave portion cp2c having a triangular (or approximately triangular) shape in a plan view. The first sub-concave portion cp1a, the second sub-concave portion cp1b, and the fifth sub-concave portioncp1c may be continually arranged along the second side surface ss2 of the first partition wall PW1. Likewise, the third sub-concave portion cp2a, the fourth sub-concave portion cp2b, and the sixth sub-concave portion cp2c may be continually arranged along the third side surface ss3 of the partition wall PW.

In a plan view, two edges defining the first sub-concave portion cp1a, two edges defining the second sub-concave portion cp1b, and two edges defining the fifth sub-concave portion cp1c may each form a third angle θ3, which may be less than or equal to 90°. When the third angle θ3 is 70° (or about 70°) to 90° (or about 90°), a material for forming the planarization layer 350 may relatively more uniformly fill the valley area VA, and in ranges different from the range above, a portion of the valley area VA may not be filled with the material for forming the planarization layer 350. The first concave portion cp1 and the second concave portion cp2 may be arranged to face each other and may have an axially symmetrical (or approximately symmetrical) shape with respect to a virtual line extending along the center of the valley area VA. The first concave portion cp1 and the second concave portion cp2 arranged to face each other may be connected to the valley area VA and may have a star (or approximately star) shape having six horns in a plan view.

As the number of vertices vp of each of the first concave portion cp1 and the second concave portion cp2 increases, the material for forming the planarization layer 350 (see FIG. 7) may be easily spread to relatively more uniformly fill the valley area VA. Shapes of the first concave portion cp1 and the second concave portion cp2 may be determined depending on the width of the partition walls PW and the distance between the partition walls PW.

Referring to FIG. 9D, the first concave portion cp1 and the second concave portion cp2 may be arranged to face each other, but may not have a symmetrical shape. For example, FIG. 9D illustrates a case where the first concave portion cp1 has three vertices vp, and the second concave portion cp2 has one vertex vp. The first concave portion cp1 may include a first sub-concave portion cp1a, a second sub-concave portion cp1b, and a fifth sub-concave portion cp1c having a triangular (or approximately triangular) shape in a plan view. In a plan view, two edges defining the first sub-concave portion cp1a, two edges defining the second sub-concave portion cp1b, and two edges defining the fifth sub-concave portion cp1c may each form a third angle θ3, which may be less than or equal to 90°. According to some embodiments, the third angle θ3 may be 40° (or about 40°) to 90° (or about 90°). Two edges defining the second concave portion cp2 may form a first angle θ1, which may be 70° (or about 70°) to 90° (or about 90°).

According to embodiments, for the material for forming the planarization layer 350 of the display apparatus 1 to relatively more uniformly fill the valley area VA between the partition walls PW, the concave portions each having at least one vertex along the facing surfaces of the first partition wall PW1 and the second partition wall PW2 may be formed. Based on this structure, the planarization layer 350 may relatively more uniformly fill the valley area VA between the partition walls PW, and thus, defects of the planarization layer 350, such as bubbles or wrinkles, may be reduced, and thus, the display apparatus 1 may have relatively improved reliability.

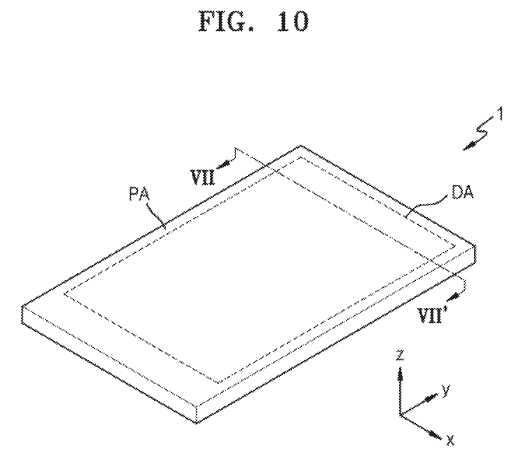

FIG. 10 is a schematic perspective view of the display apparatus 1 according to some embodiments.

Referring to FIG. 10, the display apparatus 1 may display a motion image or a static image and may be used as a display screen not only of a portable electronic device, such as a mobile phone, a smartphone, a tablet PC, a mobile communication terminal, an electronic notebook, an electronic book, a PMP, a navigation device, or a UMPC, but also of various electronic devices, such as a television, a notebook computer, a monitor, an advertising board, and an IOT device.

According to some embodiments, the display apparatus 1 may be arranged in a vehicle. For example, the display apparatus 1 may be arranged in at least one of a cluster, a center fascia, or a dashboard of a vehicle. When the display apparatus 1 is arranged in the vehicle, light emitted from the display apparatus 1 may have a proceeding path limited to a certain direction such that the light may not be reflected from a window glass.

According to some embodiments, the display apparatus 1 may have a rectangular shape in a plan view. For example, the display apparatus 1 may have a rectangular planar shape having a short side in an x direction and a long side in a y direction as illustrated in FIG. 1. A corner at which the short side in the x direction and the long side in the y direction meet each other may be curved to have a curvature (e.g., a set or predetermined curvature) or may be right-angled. The planar shape of the display apparatus 1 is not limited to a rectangular shape and may include other shapes, such as a polygonal shape, an oval shape, or an amorphous shape.

The display apparatus 1 may include the display area DA and the peripheral area PA entirely surrounding the display area DA. A plurality of light-emitting diodes and a plurality of pixel circuits may be arranged in the display area DA. The peripheral area PA may be an area where an image is not provided. External circuits, lines, and pads configured to drive the pixel circuits may be arranged in the peripheral area PA. The pads may be exposed rather than being covered by an insulating layer and may be electrically connected to a printed circuit board or a driver integrated circuit (IC).

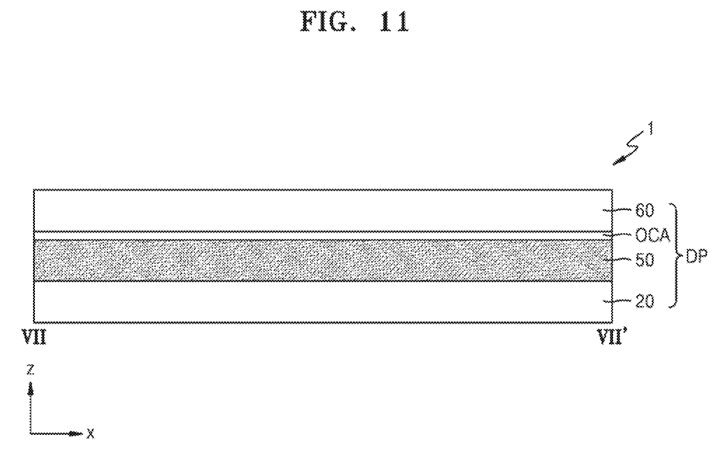

FIG. 11 is a schematic cross-sectional view of the display apparatus 1 taken along the line VII-VII' of FIG. 10, according to some embodiments.

Referring to FIG. 11, the display apparatus 1 may include the display panel DP. The display panel DP may include the image generation layer 20, the optical functional layer 50, and the cover window 60.

The image generation layer 20 may include display elements (or light-emitting elements) emitting light to display an image. The display element may include a light-emitting diode, for example, an organic light-emitting diode including an organic emission layer. According to some embodiments, the light-emitting diode may include an inorganic light-emitting diode including an inorganic material. The inorganic light-emitting diode may include a PN junction diode including inorganic semiconductor-based materials. When a voltage is applied to the PN junction diode in a normal direction, holes and electrons may be injected into the PN junction diode and energy generated by recombination of the holes and the electrons may be converted into light energy, and thus, light of a certain color may be emitted. The inorganic light-emitting diode described above may have a width that is several to hundreds of micrometers or several to hundreds of nanometers.

According to some embodiments, the image generation layer 20 may include a quantum dot light-emitting diode. For example, an emission layer of the image generation layer 20 may include an organic material, an inorganic material, quantum dots, an organic material and quantum dots, or an inorganic material and quantum dots.

The optical functional layer 50 may limit the path of light emitted from the image generation layer 20 so that the light may or may not proceed in a certain direction. For example, the optical functional layer 50 may include a plurality of light-shielding lines apart from each other by a certain distance and may limit a component in a certain direction of the light emitted from the image generation layer 20. The optical functional layer 50 may include a reflection prevention layer. The reflection prevention layer may reduce the reflectivity of light (external light) incident toward the display panel DP from the outside through the cover window 60. The reflection prevention layer may include a phase retarder and a polarizer. According to some embodiments, the reflection prevention layer may include a black matrix and color filters. The color filters may be arranged by taking into account a color of light emitted from each of the light-emitting diodes of the image generation layer 20.

The cover window 60 may be arranged on the optical functional layer 50. The cover window 60 may be coupled to the optical function layer 50 through an adhesive layer, such as an OCA, arranged therebetween.

According to some embodiments, an input sensing layer may be arranged between the image generation layer 20 and the optical functional layer 50. The input sensing layer may be directly formed on the image generation layer 20 or after being separately formed from the image generation layer 20, may be coupled to the image generation layer 20 through an adhesive layer, such as an OCA. According to some embodiments, the input sensing layer may be arranged between the optical functional layer 50 and the cover window 60.

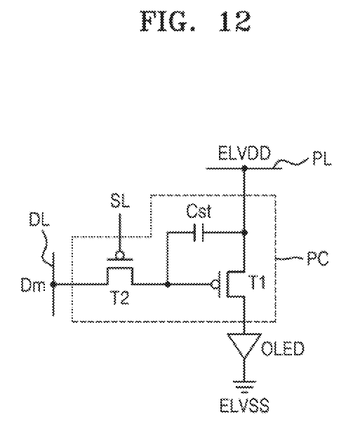

FIG. 12 is a schematic equivalent circuit diagram of a light-emitting diode and a circuit connected to the light-emitting diode, according to some embodiments. Although FIG. 12 illustrates various components in a circuit of a light-emitting diode, embodiments according to the present disclosure are not limited thereto, and according to various embodiments, the circuit may include additional components without departing from the spirit and scope of embodiments according to the present disclosure.

Referring to FIG. 12, a pixel may emit light through a display element, for example, an organic light-emitting diode OLED, and the organic light-emitting diode OLED may be electrically connected to a pixel circuit PC.

The pixel circuit PC may include a first transistor T1, a second transistor T2, and a storage capacitor Cst. Each of the first transistor T1 and the second transistor T2 may include a gate (or a gate electrode), a first terminal (or a first electrode), and a second terminal (or a second electrode). Each first terminal may correspond to a source or a drain, and each second terminal may be a different terminal from the first terminal. For example, when the first terminal corresponds to the source (a source electrode), the second terminal may correspond to the drain (a drain electrode).

The second transistor T2 may include a switching transistor, may be connected to a scan line SL and a data line DL, and may be configured to transmit, to the first transistor T1, a data voltage (or a data signal Dm) input from the data line DL, based on a switching voltage (or a switching signal) input from the scan line SL. The storage capacitor Cst may be connected to the second terminal of the second transistor T2 and a driving voltage line PL and may be configured to store a voltage corresponding to the difference between a voltage received from the second transistor T2 and a driving voltage ELVDD supplied to the driving voltage line PL.

The first transistor T1 may include a driving transistor, may be connected to the driving voltage line PL and the storage capacitor Cst, and may be configured to control a driving current flowing from the driving voltage line PL through the light-emitting diode LED according to a value of the voltage stored in the storage capacitor Cst. The light-emitting diode LED may emit light having a certain brightness according to the driving current. A second electrode (for example, a cathode) of the light-emitting diode LED may receive a common voltage ELVSS.

FIG. 12 illustrates that the pixel circuit PC includes two transistors and one storage capacitor. However, according to some embodiments, the pixel circuit PC may include three or more transistors.

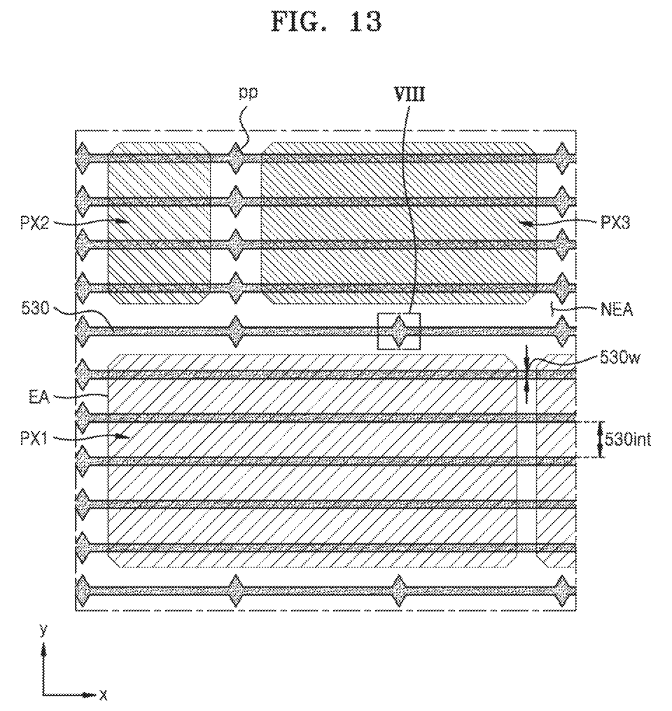

FIG. 13 is a schematic plan view of a portion of the display panel DP according to some embodiments.

Referring to FIG. 13, a first pixel PX1, a second pixel PX2, and a third pixel PX3 may be arranged in the display area DA (see FIG. 10) of the display apparatus 1 (see FIG. 10). Each of the first to third pixels PX1 to PX3 may be defined by an emission area EA of each of the light-emitting diodes.

The first pixel PX1 may emit light of a first wavelength band. For example, the first pixel PX1 may emit light of a wavelength in a range of 450 nm (or about 450 nm) to 495 nm (or about 495 nm). The second pixel PX2 may emit light of a second wavelength band. For example, the second pixel PX2 may emit light of a wavelength in a range of 630 nm (or about 630 nm) to 780 nm (or about 780 nm). The third pixel PX3 may emit light of a third wavelength band. For example, the third pixel PX3 may emit light of a wavelength in a range of 495 nm (or about 495 nm) to 570 nm (or about 570 nm).

In a plan view, each of the first to third pixels PX1 to PX3 may have a quadrangular (or approximately quadrangular) shape. Corners of the quadrangular shape may be curved or chamfered. According to some embodiments, the first to third pixels PX1 to PX3 may have other polygonal shapes, circular shapes, or oval shapes.

The size (or area) of each of the first to third pixels PX1 to PX3 may be different from each other. For example, the size (or area) of the second pixel PX2 may be less than the size (or area) of the first pixel PX1 and the third pixel PX3, and the size (or area) of the first pixel PX1 may be greater than the size (or area) of the third pixel PX3. However, the disclosure is not limited thereto. Various modifications are possible. For example, the size (or area) of each of the first to third pixels PX1 to PX3 may be the same (or substantially the same) as each other.

The first pixel PX1 may be provided in a plural number, and the plurality of first pixels PX1 may be arranged to be apart from each other in an x direction. Each of the second pixel PX2 and the third pixel PX3 may be provided in a plural number, and the plurality of second pixels PX2 and the plurality of third pixels PX3 may be alternately arranged to be apart from each other in the x direction. A pixel row formed by the first pixels PX1 arranged in the x direction and a pixel row formed by the second pixels PX2 and the third pixels PX3 alternately arranged in the x direction may be alternately arranged in a y direction. However, embodiments according to the present disclosure are not limited thereto, and the pixels may be variously arranged, for example, as a PenTile^{TM} structure, a stripe structure, a mosaic structure, or a delta structure.

The display apparatus 1 (see FIG. 10) may include a plurality of light-shielding lines 530 reflecting or absorbing light emitted from the first to third pixels PX1 to PX3. One pixel may overlap the plurality of light-shielding lines 530. The light-shielding lines 530 may extend in the x direction and may be apart from each other in the y direction by a first distance of 530 int. The first distance of 530int may be a distance from an edge of a first light-shielding line to an edge of a second light-shielding line adjacent to the first light-shielding line. The first distance of 530int may have a range of 10 μm (or about 10 μm) to 60 μm (or about 60 μm). A width 530w of the light-shielding line 530 may be 2 μm (or about 2 μm) to 10 μm (or about 10 μm).

The light-shielding lines 530 may limit a component in a certain direction of the light emitted from the first to third pixels PX1 to PX3. For example, when the component in the y direction of the light emitted from the first to third pixels PX1 to PX3 exceeds a certain value and has an angle of emission greater than or equal to a cut-off angle, the emitted light may be absorbed or reflected by the light-shielding line 530.

The light-shielding lines 530 may be arranged to be apart from each other in the x direction and may have protrusion portions pp protruding in directions crossing the x direction, for example, a +y direction and a -y direction. The protrusion portions pp may be arranged to be apart from each other along the light-shielding lines 530. The protrusion portions pp may be arranged in a non-emission area NEA outside the emission area EA not to overlap the emission area EA.

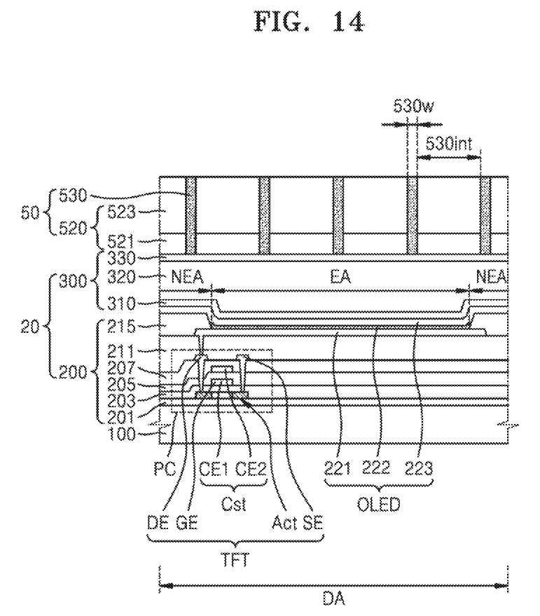

FIG. 14 is a schematic cross-sectional view of a portion of the display panel DP according to some embodiments.

Referring to FIG. 14, the display apparatus 1 may include the substrate 100, the image generation layer 20 on the substrate 100, and the optical functional layer 50 on the image generation layer 20. The image generation layer 20 may include a circuit-diode layer 200 and the encapsulation layer 300.

The pixel circuit PC may be formed on the substrate 100, and the light-emitting diode, for example, the organic light-emitting diode OLED, may be formed on the pixel circuit PC.

The buffer layer 201 may be formed between the substrate 100 and the pixel circuit PC. The buffer layer 201 may prevent or reduce penetration of contaminants or impurities into the pixel circuit PC. The buffer layer 201 may include an inorganic insulating material, such as silicon nitride, silicon oxynitride, and silicon oxide, and may include a single-layered or multi-layered structure including the inorganic insulating material described above.

The pixel circuit PC may include a plurality of transistors and a storage capacitor as described above with reference to FIG. 12. With respect to this aspect, FIG. 14 illustrates a thin-film transistor TFT corresponding to the first transistor T1 and the storage capacitor Cst.

The thin-film transistor TFT may include a semiconductor layer Act on the buffer layer 201 and a gate electrode GE overlapping a portion of the semiconductor layer Act. The semiconductor layer Act may include a silicon-based semiconductor material, for example, polysilicon. According to some embodiments, the semiconductor layer Act may include an oxide-based semiconductor material.

The first gate insulating layer 203 may be arranged between the semiconductor layer Act and the gate electrode GE. The first gate insulating layer 203 may include an inorganic insulating material, such as silicon oxide, silicon nitride, and silicon oxynitride, and may include a single-layered or multi-layered structure including the inorganic insulating material described above.

The gate electrode GE may include a conductive material including Mo, Al, Cu, Ti, etc. and may include a single-layered or multi-layered structure including the material described above.

The storage capacitor Cst may include the lower electrode CE1 and the upper electrode CE2 overlapping each other. According to some embodiments, the lower electrode CE1 of the storage capacitor Cst may include the first gate electrode GE1. In other words, the first gate electrode GE1 may include the lower electrode CE1 of the storage capacitor Cst. For example, the first gate electrode GE1 and the lower electrode CE1 of the storage capacitor Cst may be integrally formed with each other.

The first interlayer insulating layer 205 may be arranged between the lower electrode CE1 and the upper electrode CE2 of the storage capacitor Cst. The first interlayer insulating layer 205 may include an inorganic insulating material, such as silicon oxide, silicon nitride, and silicon oxynitride, and may include a single-layered or multi-layered structure including the inorganic insulating material described above.

The upper electrode CE2 of the storage capacitor Cst may include a low-resistance conductive material, such as Mo, Al, Cu, and/or Ti, and may include a single-layered or multi-layered structure including the material described above.

The second interlayer insulating layer 207 may be arranged on the storage capacitor Cst. The second interlayer insulating layer 207 may include an inorganic insulating material, such as silicon oxide, silicon nitride, and silicon oxynitride, and may include a single-layered or multi-layered structure including the inorganic insulating material described above.

A drain electrode DE and a source electrode SE may be arranged on the second interlayer insulating layer 207. Each of the drain electrode DE and the source electrode SE may be electrically connected to the semiconductor layer Act. The drain electrode DE and the source electrode SE may include Al, Cu, and/or Ti and may include a layer or layers including the material described above. For example, the drain electrode DE and the source electrode SE may have a tri-layered structure of a Ti layer/an Al layer/a Ti layer.

The first organic insulating layer 211 may be arranged on the drain electrode DE and the source electrode SE. The first organic insulating layer 211 may include an organic insulating material. The organic insulating material may include acryl, BCB, polyimide, or HMDSO.

The light-emitting diode, for example, the organic light-emitting diode OLED, may be arranged on the first organic insulating layer 211.

The pixel electrode 221 of the organic light-emitting diode OLED may include a reflective layer including Ag, Mg, Al, Pt, Pd, Au, Ni, Nd, Ir, Cr, or a compound thereof. According to some embodiments, the pixel electrode 221 may further include a conductive oxide layer above and/or below the reflective layer described above. The conductive oxide layer may include ITO, IZO, ZnO, In₂O₃, IGO, and/or AZO. According to some embodiments, the pixel electrode 221 may have a tri-layered structure of ITO/Ag/ITO layers.

The bank layer 215 may be arranged on the pixel electrode 221. The bank layer 215 may include an opening overlapping the pixel electrode 221 and may cover an edge of the pixel electrode 221. The opening of the bank layer 215 may define the emission area EA of the organic light-emitting diode OLED emitting light. The outside of the emission area EA may be defined as the non-emission area NEA. The bank layer 215 may include an organic insulating material.

The intermediate layer 222 may include an emission layer including an organic material. The emission layer may include a high or low molecular-weight organic material emitting light of a certain color. According to some embodiments, a first functional layer and a second functional layer which are common layers arranged throughout the display area may be arranged above and/or below an emission layer. The first functional layer may include, for example, a hole transport layer (HTL), or an HTL and a hole injection layer (HIL). The second functional layer may include an electron transport layer (ETL) and/or an electron injection layer (EIL). According to some embodiments, the second functional layer may be omitted.

The opposite electrode 223 may include a conductive material having a low work function. For example, the opposite electrode 223 may include a transparent (or transflective) layer including Ag, Mg, Al, Pt, Pd, Au, Ni, Nd, Ir, Cr, Li, Ca, or an alloy thereof. Alternatively, the opposite electrode 223 may further include a layer, such as ITO, IZO, ZnO, or In₂O₃, on the transparent (or transflective) layer including the material described above.

The organic light-emitting diode OLED may be covered by the encapsulation layer 300. The encapsulation layer 300 may include at least one organic encapsulation layer and at least one inorganic encapsulation layer. According to some embodiments, the encapsulation layer 300 may include the first inorganic encapsulation layer 310, the second inorganic encapsulation layer 330, and the organic encapsulation layer 320 therebetween.

The first and second inorganic encapsulation layers 310 and 330 may include one or more inorganic materials from among aluminum oxide (Al₂O₃), titanium oxide (TiO), tantalum oxide (TA₂O₅), hafnium oxide (HfO₂), zinc oxide (ZnO), silicon oxide (SiOₓ), silicon nitride (SiNₓ), and silicon oxynitride (SiON). The first and second inorganic encapsulation layers 310 and 330 may include a single layer or layers including the material described above. The organic encapsulation layer 320 may include a polymer-based material. The polymer-based material may include acryl-based resins, epoxy-based resins, polyimide, polyethylene, etc. According to some embodiments, the organic encapsulation layer 320 may include acrylate.

Thicknesses of the first and second inorganic encapsulation layers 310 and 330 may be different from each other. The thickness of the first inorganic encapsulation layer 310 may be greater than the thickness of the second inorganic encapsulation layer 330. Alternatively, the thickness of the second inorganic encapsulation layer 330 may be greater than the thickness of the first inorganic encapsulation layer 310, or the thicknesses of the first and second inorganic encapsulation layer 310 and 330 may be the same as each other.

The optical functional layer 50 may be arranged on the encapsulation layer 300. The optical functional layer 50 may include an organic layer 520 and the light-shielding lines 530 arranged in the organic layer 520. The organic layer 520 may include portions apart from each other and may have grooves GV defined by the portions apart from each other. The plurality of grooves GV may be arranged by a constant distance, for example, the first distance of 530int.

According to some embodiments, the organic layer 520 may include a first transmission layer 521 and a second transmission layer 523 sequentially stacked. The first transmission layer 521 may include a transmissive organic material. Also, the first transmission layer 521 may include a material having excellent spreadability above the encapsulation layer 300, for the coating characteristic of the second transmission layer 523. The first transmission layer 521 may include a photosensitive organic material.

According to some embodiments, the first transmission layer 521 may include an organic material, such as an epoxy-based resin, an acryl-based resin, or an imide-based resin. According to some embodiments, the first transmission layer 521 may include ethylene glycol di(meth)acrylate-based polymers, diethylene glycol di(meth)acrylate-based polymers, triethylene glycol di(meth)acrylate-based polymers, 1,6-hexandiol di(meth)acrylate-based polymers, pentaerythritol tri(meth)acrylate-based polymers, pentaerythritol tetra(meth)acrylate-based polymers, dipentaerythritol penta(meth)acrylate-based polymers, dipentaerythritol hexa(meth)acrylate-based polymers, bisphenol A epoxy(meth)acrylate-based polymers, ethylene glycol monomethyl ether(meth)acrylate-based polymers, trimethylol propane tri(meth)acrylate-based polymers, trisacryloyloxyethylphosphate-based polymers, cardo epoxy diacrylate-based polymers, etc. According to some embodiments, the first transmission layer 521 may be omitted.

The second transmission layer 523 may be arranged on the first transmission layer 521 and may be thicker than the first transmission layer 521. The second transmission layer 523 may include acryl-based resins (for example, polymethylmethacrylate, polyacrylic acid, etc.), (ethylh)exyl acrylate, pentafluoropropyl acrylate, poly(ethylene glycol) dimethacrylate, or ethylene glycol dimethacrylate. The first transmission layer 521 and the second transmission layer 523 may include materials having the same or substantially the same refractive index.

The organic layer 520 may include the grooves GV apart from each other by the first distance of 530int. For example, the organic layer 520 may include portions apart from each other by a certain distance, and the groove GV may be defined between the portions apart from each other.

Each of the light-shielding lines 530 may fill the groove GV. For example, a material for forming the light-shielding line 530 may be spread to fill the groove GV and then cured to form the light-shielding line 530. The light-shielding lines 530 may include an organic material including a light-shielding material. The light-shielding material may include black dyes, Cr particles, or metal oxide, such as molybdenum oxide.

FIG. 14 illustrates that the light-shielding line 530 is vertically formed with respect to an upper surface of the substrate 100. However, the disclosure is not limited thereto. Side surfaces of the light-shielding lines 530 may be provided to have a tilt angle with respect to the upper surface of the substrate 100.

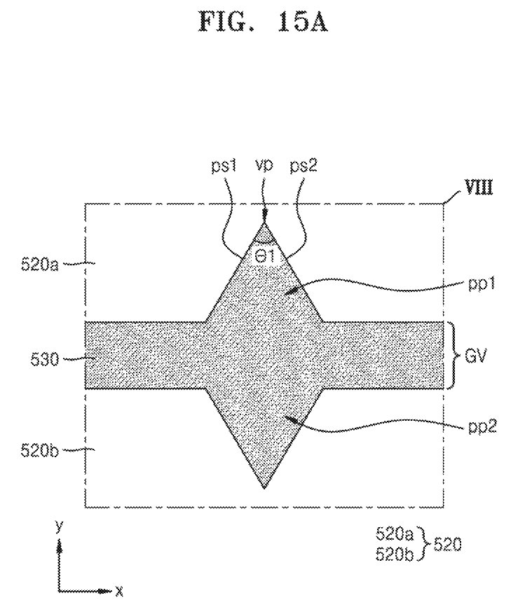

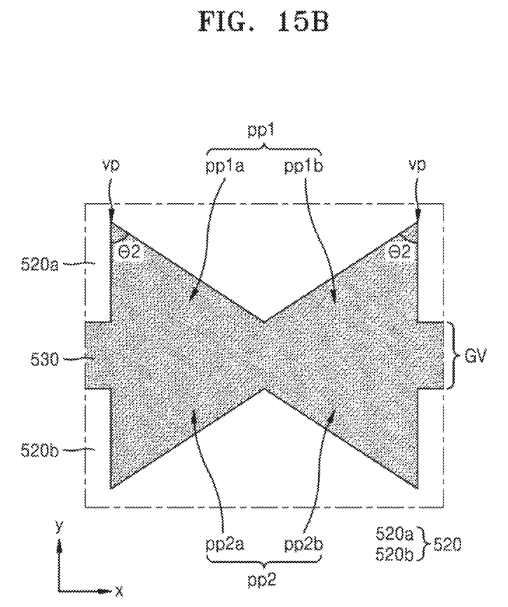

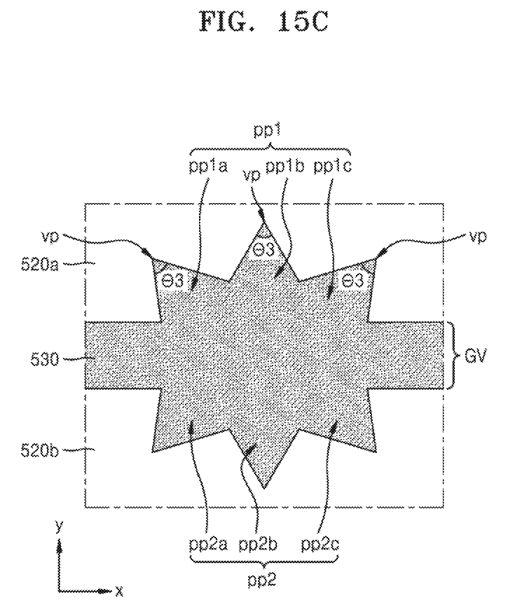

FIG. 15A is an enlarged schematic plan view of a portion of the display panel DP, the portion corresponding to region VIII of FIG. 13, according to some embodiments. FIGS. 15B and 15c are each a plan view of a portion of the display panel DP according to some embodiments. FIGS. 15B and 15C are enlarged schematic views of the portion corresponding to region VIII of FIG. 13.

Referring to FIG. 15A, the organic layer 520 and the light-shielding line 530 may be arranged in the display area DA (see FIG. 13). The organic layer 520 may be separated into portions apart from each other in a y direction. For example, the organic layer 520 may include a first portion 520a and a second portion 520b apart from each other in the y direction, and the groove GV exposing an upper surface of the second inorganic encapsulation layer 330 (see FIG. 14) may be defined between the first portion 520a and the second portion 520b.

The groove GV may have a portion protruding in a direction toward the first portion 520a and a portion protruding in a direction toward the second portion 520b in a plan view. The light-shielding line 530 may be formed by filling the groove GV with a material for forming the light-shielding line 530. The light-shielding line 530 may include a first protrusion portion pp1 and a second protrusion portion pp2 corresponding to the protrusion portions of the groove GV.

The first protrusion portion pp1 may have one vertex vp at which two edges, namely, first and second edges ps1 and ps2, extending in different directions intersect in a plan view. For example, the first protrusion portion pp1 may have the first edge ps1 and the second edge ps2, and the first edge ps1 and the second edge ps2 may meet each other at the vertex vp. That is, the first protrusion portion pp1 may have a triangular (or approximately triangular) shape in a plan view. The first edge ps1 and the second edge ps2 may form a first angle θ1, and the first angle θ1 may be less than or equal to 90° (or about 90°). When the first angle θ1 is 70° (or about 70°) to 90° (or about 90°), the material for forming the light-shielding line 530 may relatively more uniformly fill the groove GV, and in different ranges, a portion of the groove GV may not be filled with the material for forming the light-shielding line 530.

The first protrusion portion pp1 and the second protrusion portion pp2 may be arranged to face each other (e.g., arranged in alignment with each other). According to some embodiments, the first protrusion portion pp1 and the second protrusion portion pp2 may have an axially symmetrical (or approximately symmetrical) shape with respect to a virtual line extending along the center of the groove GV. The first protrusion portion pp1 and the second protrusion portion pp2 arranged to face each other may be connected to the groove GV and may have a diamond (or approximately diamond) shape in a plan view.

Each of the first protrusion portion pp1 and the second protrusion portion pp2 may have two or more vertices vp at which two edges extending in different directions in a plan view meet each other. FIG. 15B illustrates a case where each of the first protrusion portion pp1 and the second protrusion portion pp2 has two vertices vp, and FIG. 15C illustrates a case where each of the first protrusion portion pp1 and the second protrusion portion pp2 has three vertices vp.

First, referring to FIG. 15B, the first protrusion portion pp1 may have a first sub-protrusion portion pp1a and a second sub-protrusion portion pp1b having a triangular (or approximately triangular) shape in a plan view. The second protrusion portion pp2 may have a third sub-protrusion portion pp2a and a fourth sub-protrusion portion pp2b having a triangular (or approximately triangular) shape in a plan view. The first sub-protrusion portion pp1a and the second sub-protrusion portion pp1b may be continually arranged along a side surface of the first portion 520a of the organic layer 520. Likewise, the third sub-protrusion portion pp2a and the fourth sub-protrusion portion pp2b may be continually arranged along a side surface of the second portion 520b of the organic layer 520.

Two edges defining the first sub-protrusion portion pp1a and two edges defining the second sub-protrusion portion pp1b in a plan view may each form a second angle θ2, and the second angle θ2 may be less than or equal to 90°. When the second angle θ2 is 50° (or about 50°) to 90° (or about 90°), a material for forming the light-shielding line 530 may relatively more uniformly fill the groove GV.

The first protrusion portion pp1 and the second protrusion portion pp2 may be arranged to face each other and may have an axially symmetrical (or approximately symmetrical) shape with respect to a virtual line extending along the center of the groove GV. The first protrusion portion pp1 and the second protrusion portion pp2 arranged to face each other may be connected to the groove GV and may have a star shape having four horns in a plan view.

Referring to FIG. 15C, each of the first protrusion portion pp1 and the second protrusion portion pp2 may have three vertices vp. For example, the first protrusion portion pp1 may include a first sub-protrusion portion pp1a, a second sub-protrusion portion pp1b, and a fifth sub-protrusion portion pp1c having a triangular (or approximately triangular) shape in a plan view. The second protrusion portion pp2 may include a third sub-protrusion portion pp2a, a fourth sub-protrusion portion pp2b, and a sixth sub-protrusion portion pp2c having a triangular (or approximately triangular) shape in a plan view. The first sub-protrusion portion pp1a, the second sub-protrusion portion ppb1, and the fifth sub-protrusion potion ppc1c may be continually arranged along a side surface of the first portion 520a of the organic layer 520. Likewise, the third sub-protrusion portion pp2a, the fourth sub-protrusion portion pp2b, and the sixth sub-protrusion portion pp2c may be continually arranged along a side surface of the second portion 520b of the organic layer 520.

In a plan view, two edges defining the first sub-protrusion portion pp1a, two edges defining the second sub-protrusion portion pp1b, and two edges defining the fifth sub-protrusion portion pp1c may each form a third angle θ3, which may be less than or equal to 90°. When the third angle θ3 is 70° (or about 70°) to 90° (or about 90°), a material for forming the planarization layer 350 may relatively more uniformly fill the groove GV. The first protrusion portion pp1 and the second protrusion portion pp2 may be arranged to face each other and may have an axially symmetrical (or approximately symmetrical) shape with respect to a virtual line extending along the center of the groove GV. The first protrusion portion pp1 and the second protrusion portion pp2 arranged to face each other may be connected to the groove GV and may have a star shape having six horns in a plan view.

According to embodiments, concave portions of the organic layer 520 having at least one vertex may be formed along the side surfaces of the groove GV, so that the groove GV of the organic layer 520 may be relatively more uniformly filled with the material for forming the light-shielding line 530. Thus, the light-shielding line 530 formed by filling the groove GV may have the first and second protrusion portions pp1 and pp2 corresponding to the concave portions of the organic layer 520. Based on this structure, the optical functional layer 50 may have a relatively more flat upper surface, and thus, the display apparatus 1 may provide a high quality image.

The display apparatus 1 according to embodiments may be employed by various electrode devices. An electronic device according to some embodiments may include the display apparatus 1 described above and may further include a module or a device having other additional functions in addition to the display apparatus.

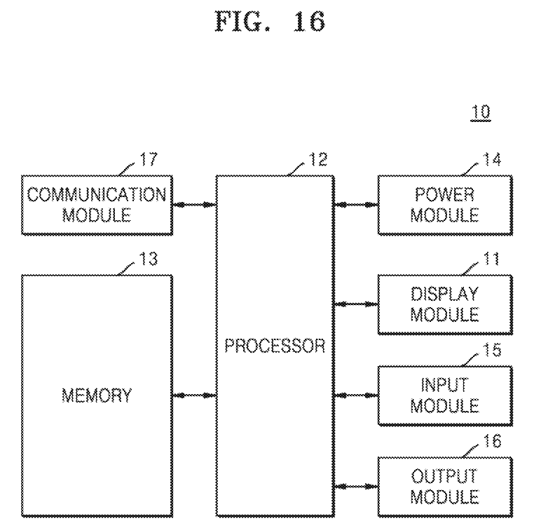

FIG. 16 is a schematic block diagram of an electronic device 10 according to some embodiments.

Referring to FIG. 16, the electronic device 10 according to some embodiments may include a display module 11, a processor 12, a memory 13, and a power module 14. The electronic device 10 may further include an input module 15, a non-image output module 16, and/or a communication module 17.

The electronic device 10 may output, through the display module 11, various information in the form of an image. When the processor 12 executes an application stored in the memory 13, image information provided by the application may be provided to a user through the display module 11. The power module 14 may include a power supply module, such as a power adaptor or a battery device, and a power conversion module configured to convert power supplied from the power supply module and generate power necessary for operations of the electronic device 10. The input module 15 may provide input information to the processor 12 and/or the display module 11. The non-image output module 16 may receive information, except for an image from the processor 12, for example, information about a sound, a haptic input, light-emission, etc., and provide the received information to the user. The communication module 17 may be configured to perform transmission and reception of information between the electronic device 10 and an external device and may include a receiver and a transmitter.

According to some embodiments, the processor 12 may be provided by being divided into two or more processors in a functional or structural perspective. For example, the processor 12 may include a main processor as a first driving chip including a CPU and an auxiliary processor as a second driving chip including a controller configured to receive an image signal from the main processor and process the image signal according to the interface specifications of the display module 11.

The memory 15 may include at least one of a non-volatile memory or a volatile memory. The memory 15 may store data information necessary for operations of the processor 12 or the display module 11. When the processor 12 executes an application stored in the memory 15, an image data signal and/or an input control signal may be transmitted to the display module 11, and the display module 11 may be configured to process the received signal and output image information through a display screen.

The power module 14 may include a power supply module, such as a power adaptor or a battery device, and a power conversion module configured to convert power supplied from the power supply module and generate power necessary for operations of the electronic device 10. The power conversion by the power conversion module may include direct current (DC)-DC conversion, alternating current (AC)-DC conversion, and DC-AC conversion and is not limited thereto.

The input module 15 may provide input information to the processor 12 and/or the display module 11. The input module 15 may include not only a physical button, a keyboard, and a microphone, but also various sensor modules. Examples of the sensor modules may include not only a touch sensor, a pressure sensor, a distance sensor, a position sensor, a digitizer, a motion recognition sensor, a camera sensor, a light reception sensor, a photoelectric conversion sensor, and a temperature sensor, but also biometric sensors, such as a blood-pressure sensor, a blood-sugar sensor, an electrocardiogram sensor, a heart rate sensor, etc.

The non-image output module 16 may receive information except for an image from the processor 12 and provide the information to the user. Examples of the non-image output module 16 may include a sound module, a haptic module, a light-emission module, etc. and may also include other functionally intrinsic modules (for example, a cooling module of a refrigerator, etc.) of the electronic device 10.

The communication module 17 may be configured to perform transmission and reception of information between the electronic device 10 and an external device and may include a receiver and a transmitter. The communication module 17 may include various wireless communication modules, such as a mobile communication module, a WiFi module, a Bluetooth module, etc., or various wired communication modules.

At least one of the components of the electronic device 10 described above may be included in the display apparatus 1 according to the embodiments described above. Also, some of separate modules functionally included in one module may be included in the display apparatus 1 and the others may be provided separately from the display apparatus 1. For example, the display apparatus 1 may include the display module 11, and the processor 12, the memory 13, and the power module 14 may be provided as other devices in the electronic device 11, rather than being provided in the display apparatus 1. As another example, the power module 14 may be provided in the display apparatus 1 and may provide a power supply to the processor 12 and the memory 13 provided in the electronic device 11 rather than the display apparatus 1. However, the disclosure is not limited thereto.

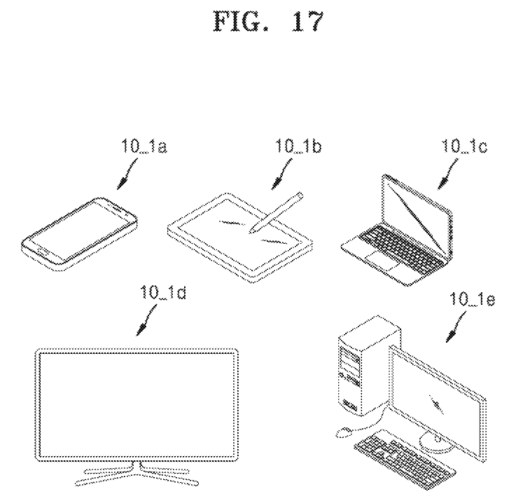

FIGS. 17 to 19 are schematic views of electronic devices according to various embodiments.

FIG. 17 illustrates a smartphone 10_1a, a tablet PC 10_1b, a laptop computer 10_1c, a TV 10_1d, and a monitor 10_1e for a desk, as examples of the electronic devices.

The smartphone 10_1a may include an input module, such as a touch sensor, etc., and a communication module, in addition to a display module. The smartphone 10_1a may process information received through the communication module or other input modules and display the processed information through a display module of the display apparatus 1.

The tablet PC 10_1b, the laptop computer 10_1c, the TV 10_1d, and the monitor 10_1e for a desk may also include a display module and an input module, similarly as the smartphone 10_1a, and may further include a communication module according to cases.

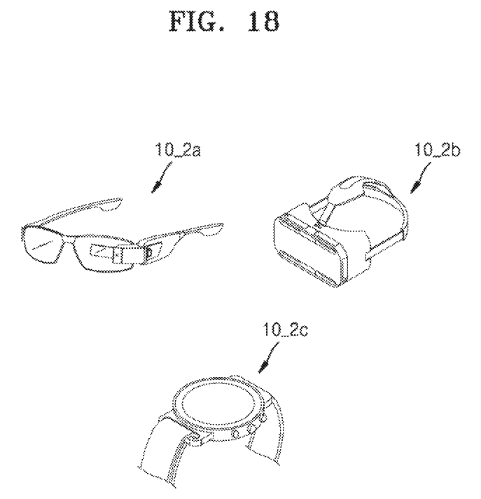

FIG. 18 illustrates a case where an electronic device including a display module is employed by a wearable electronic device. The wearable electronic device may include smart glasses 10_2a, an HMD 10_2b, a smart watch 10_2c, etc.

The smart glasses 10_2a and the HMD 10_2b may include a display module configured to project a display image and a reflector configured to reflect the projected display screen and provide the display screen to a user's eye, so as to provide a screen of virtual reality (VR) or augmented reality (AR) to the user.

The smart watch 10_2c may include a biometric sensor as an input device and may provide biometric information recognized through the biometric sensor to the user through a display module.

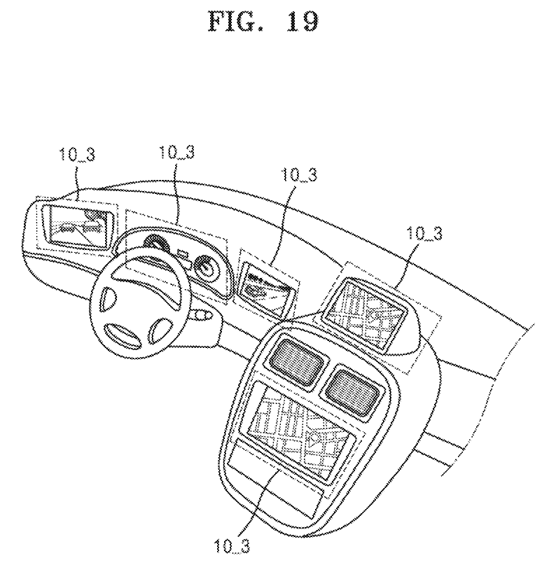

FIG. 19 illustrates a case where an electronic device 10_3 including the display module includes a vehicle. For example, the electronic device 10_3 may be used as a gauge or a center fascia of the vehicle or may be used as a center information display (CID) arranged on a dashboard of the vehicle or as a room mirror display substituting a side-view mirror.

According to some embodiments, the electronic device in which the display apparatus 1 according to embodiments is included, may include not only devices mainly including a screen display, such as an advertisement board, an electronic display board, a game machine, etc., but also various home appliances for displaying information through a display module, such as a refrigerator, a laundry machine, a dryer, an air conditioner, a robot cleaner, etc. Also, when a display module has a light-transmission function, the display module may be employed by the electronic device, such as a smart window or a transparent display apparatus for displaying a background and a display image together. Types of the electronic device according to embodiments are not limited to the examples described above, and various other electronic devices may also be provided.

According to some embodiments as described above, the display panel having relatively improved reliability and display quality by uniformly filling an organic material between organic layers arranged to be adjacent to each other, and the electronic device including the display panel, may be realized. However, the scope of the disclosure is not limited by these effects.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by one of ordinary skill in the art that various changes in form and details may be made therein without departing from the spirit and scope as defined by the following claims.

What is claimed is:

1. A display panel comprising:
a substrate comprising an opening;
a plurality of light-emitting diodes in a display area surrounding the opening;
a first partition wall in a non-display area between the opening and the display area, the first partition wall surrounding the opening; and
a second partition wall in the non-display area, between the opening and the first partition wall, and surrounding the opening,
wherein the first partition wall comprises a first surface toward the second partition wall and a second surface opposite to the first surface, wherein the first surface has a first concave portion open toward the second partition wall, and
the second partition wall comprises a third surface toward the first partition wall and a fourth surface opposite to the third surface, wherein the third surface has a second concave portion open toward the first partition wall.

2. The display panel of claim 1, wherein the first concave portion and the second concave portion face each other.

3. The display panel of claim 1, wherein the first concave portion and the second concave portion are each provided as a plurality,
the plurality of first concave portions are spaced apart from each other along the first surface, and
the plurality of second concave portions are spaced apart from each other along the third surface.

4. The display panel of claim 1, wherein each of the first concave portion and the second concave portion has at least one vertex at which two edges extending in different directions intersect in a plan view.

5. The display panel of claim 4, wherein the two edges intersecting each other at the at least one vertex forms an acute angle in the plan view.

6. The display panel of claim 5, wherein the acute angle formed by the two edges meeting each other at the at least one vertex is greater than 40°.

7. The display panel of claim 4, wherein the first concave portion and the second concave portion have an axially symmetrical shape in the plan view.

8. The display panel of claim 4, wherein the number of vertices of the first concave portion is different from the number of vertices of the second concave portion.

9. The display panel of claim 1, further comprising an overhang structure arranged in the non-display area and surrounding the opening,
wherein the overhang structure comprises:
a first layer in which a groove is defined; and
second layers arranged at both sides of the groove,
wherein each of the second layers comprises an overhang portion hanging over the groove and extending toward each other.

10. The display panel of claim 9, wherein the overhang portion is tilted toward the groove and forms an angle of 0° to 40° with a virtual plane parallel to an upper surface of the substrate.

11. The display panel of claim 9, wherein the first layer comprises an organic insulating material, and
the second layers comprise a metal material.

12. A display panel comprising:
a substrate comprising a display area and a peripheral area outside the display area;
a plurality of light-emitting diodes in the display area;
an encapsulation layer on the plurality of light-emitting diodes; and
an optical functional layer on the encapsulation layer and comprising an organic layer and a plurality of light-shielding lines, wherein the organic layer defines a plurality of grooves and the plurality of light-shielding lines are arranged in the plurality of grooves,
wherein each of the plurality of light-shielding lines comprises: a first protrusion portion extending in a first direction and protruding in a second direction crossing the first direction; and a second protrusion portion protruding in a third direction which is opposite to the second direction.

13. The display panel of claim 12, wherein the first protrusion portion and the second protrusion portion are aligned with each other.

14. The display panel of claim 13, wherein the first protrusion portion and the second protrusion portion are each provided as a plurality,
the plurality of first protrusion portions are spaced apart from each other along the plurality of light-shielding lines, and
the plurality of second protrusion portions are aligned with the plurality of first protrusion portions.

15. The display panel of claim 12, wherein
each of the first protrusion portion and the second protrusion portion has at least one vertex at which two edges extending in different directions intersect in a plan view.

16. The display panel of claim 15, wherein
the two edges intersecting each other at the at least one vertex forms an acute angle in the plan view.

17. The display panel of claim 15, wherein the acute angle formed by the two edges meeting each other at the at least one vertex is greater than 40°.

18. An electronic device comprising:
a display apparatus comprising a display panel;
a memory storing an application; and
a processor configured to execute the application and transmit an image data signal and a control signal to the display apparatus,
wherein the display panel comprises:
a first organic layer and a second organic layer on a substrate and arranged to be apart from each other by a certain distance to define a valley area or a groove; and
a third organic layer filling the valley area or the groove,
wherein the first organic layer comprises a first surface toward the second organic layer, and the second organic layer comprises a third surface toward the first organic layer,
wherein the first surface has a first concave portion open toward the second organic layer, and the third surface has a second concave portion open toward the first organic layer.

19. The electronic device of claim 18, wherein the substrate comprises an opening,
the electronic device further comprises a plurality of light-emitting diodes in a display area surrounding the opening, and
the first organic layer and the second organic layer are in a non-display area between the opening and the display area and surround the opening.

20. The electronic device of claim 18, further comprising:
a plurality of light-emitting diodes on the substrate; and
an encapsulation layer on the plurality of light-emitting diodes,
wherein the first organic layer and the second organic layer are on the encapsulation layer, and
the third organic layer comprises a light-shielding material.
